(19) United States
(12) Patent Application Publication
(10) Pub. No.: US 2007/0234174 A1
(43) Pub. Date: Oct. 4, 2007

(54) Method and Device for Error Handling in the Transmission of Data Via a Communications System

(76) Inventors: Eberhard Boehl, Reutlingen (DE); Michael Boehl, Stuttgart (DE)

Correspondence Address: KENYON & KENYON LLP, ONE BROADWAY, NEW YORK, NY, 10004, US

(21) Appl. No.: 11/578,199

(22) PCT Filed: Apr. 7, 2005
(86) PCT No.: PCT/EP05/51557

§ 371 Date: Oct. 10, 2006

(30) Foreign Application Priority Data
Apr. 8, 2004 (DE) 10 2004 018 082.2
Dec. 22, 2004 (DE) 10 2004 061 803.8

(51) Int. Cl. H03M 13/00

(52) U.S. Cl. 714/752

(57) ABSTRACT

A method and a device for error handling in the transmission of coded data in the form of at least one data word via a communications system, for the at least one data word a code data word being selected according to a specifiable coding rule, the data being represented as bits which are able to assume two different values, ones and zeros, at least one running digital sum being formed in such a way that a summed difference of the total number of the ones and the total number of the zeros is at least formed through the code data word and this running digital sum is transmitted, the running digital sum being determined to the following code data word and being compared to the one that is then transmitted, in the case of deviation, an error being detected.

### FIELD OF THE INVENTION

The invention relates to a method and a device for error handling in the transmission of coded data in the form of at least one data word via a communications systems having at least two subscribers and to a corresponding subscriber of the communications system and a corresponding computer program and computer program product, according to the generic parts of the claims.

### DESCRIPTION OF RELATED ART

Codes for the transmission of data via a communications system, especially via serial busses, differ depending on the transmission medium, the bit rate and the requirement for a timing recovery and the electromagnetic compatibility (EMC) characteristic values. For instance, in order to transmit data having up to 25 megabits/s, an optical transmission was provided in the MOST system, in order to ensure the EMC. However, in this context, electrical-optical converters are very expensive, and the plastic optical fibers used make special demands on installation in the automobile body. For this purpose, the signals in the MOST bus are coded according to the Biphase Mark Code (bifrequency code). Each information bit, in this context, is represented by two code bits. If both code bits have the same value, then this value corresponds to the value of the information bit 0. A 1 is represented by different values of the code bits. In addition, after the two code bits there always takes place a change in level, independent of the information value: code bits 00 10 10 11 00 11 01 01 . . . info. bits 0 1 1 0 0 0 1 1 . . .

In this context, the code has 100% redundancy compared to the message bits. However, if such a code bit sequence is transmitted via electrical lines, then, because of the frequent change of level, there takes place a large EMC radiation corresponding to the bit rate (at preferably zeros) and to double the bit rate (at preferably ones). Other frequency values also come about in the frequency spectrum for the transitions between ones and zeros, without substantially attenuating the dominating two frequencies. This comes about because a level change is always called for at the bit boundaries by the coding rule. If the data are transmitted without redundancy, that is, in a binary coding having the significances 1, 2, 4, 8, etc., which may also be represented in hexadecimal coding (0x0) is equivalent to binary 0000 and 0xF is equivalent to binary 1111), this has the disadvantage that, in the first place, there does not necessarily have to be a level change (constant 0x0 or 0xF) or that these take place at a similar frequency as above at each bit, provided that constantly 0x5 or 0xA is transmitted. However, since there is no code redundancy in this case, but all bits are information bits, the transmission frequency may be reduced to half the value. However, in this case, this code that is used cannot have no DC component and, at the same time, does not offer the possibility of timing recovery using a PLL (phase locked loop), since there exists no specifiable maximum bit number without level change. A PLL requires a level change for the synchronization of at least all n bits. With that, the code shows some undesired disadvantages, as was just described.

The disadvantages may be partially avoided by using a known block code, such as in “A New 8B10B Block Code for High Speed Data Transmission Over Unshielded Twisted Pair Channels”, by Alistair Coles, Hewlett Packard, October 1996. In this instance the code redundancy is approximately 25%, because instead of 8 information bits 10 code bits are transmitted. The code is with no DC component, on the average, because, as a function of the number of the transmitted ones in comparison to the zeros (running digital sum—RDS) the code word is transmitted either inverted or non-inverted. The maximum number of equal code bit values (maximum run length MRL) is 17. With that, in principle, a connection of a PLL for timing recovery would still be possible, this, however, putting high demands on the stability of the PLL, and the build-up times becoming substantially longer.

An extraordinary disadvantage of the block codes is that it is not a systematic code, and consequently there is no coding rule as there is, for instance, in the case of a hexadecimal code having a significance assignment of the corresponding code bits corresponding to their position.

This has an effect especially in the implementation of an incrementer or a comparator, because first of all, especially in the case of the incrementer, the entire code word has to be received, the code value has to be ascertained by decoding using a table, and, for the code value increased by 1, the corresponding code word is generated using a table, and which then may first be emitted again, synchronized by at least one flip-flop. For the above-named block code, there comes about, through this, a delay of at least 11 clock pulses; in the case of storing the code tables in a synchronous RAM, there even comes about a delay of at least 13 clock pulses. As was just shown, the named related art does not demonstrate optimal properties in every respect.

Especially the sum of the properties that the code used is supposed to be with no DC component and is supposed to include frequent edges because of the required timing recovery, and is supposed to offer the possibility of serial incrementing, in order to generate the network position of a node by the simple incrementing of a special control byte and by forwarding it without great delay. In this context, it is especially desirable to find an electrical design approach which clearly has lower costs, that is, in particular, can be applied without the need of shielding within the scope of the EMC compatibility.

In this context, the codes for error handling, that is, for error recognition and/or error correction, depending on powerfulness, especially powerfulness of the correction possibilities, should be provided with a different code redundancy which makes it possible to distinguish code words from non-code words or non-code data words. In that case, non-code words are just those code words that were not coded according to the coding rule provided for coding the data, and are able to be distinguished from them. In the case of a small Hamming distance, that is, error distance of the received non-code word or non-code data word from exactly one code data word makes possible the different code redundancy to conclude that the respective code data word is involved which was corrupted on the transmission route in, for instance, one bit. This possibility for correction assumes that all code words have a Hamming distance from each other of at least 2 if single bit errors are detected and a Hamming distance of at least 3 if single errors are to be corrected. In this context, it is increasingly difficult to meet this condition if there are several coding possibilities for one data word, that is, if, as a function of other conditions, either the one or the other code data word is transmitted.

At a constant code redundancy, the Hamming distance becomes correspondingly smaller if more code data words are used. The alternative transmission of various code words is required, as was mentioned before, if, for example, a code has to be without a DC component, on the average. This is required and possible, for example in response to different transmitting possibilities via various transmitting media (electrical, optical). In this context, it is then permitted that, in order to achieve freedom from a DC component, for instance, the inverted code data word is transmitted instead of the actual code data word exactly when it balances out better the number of ones and zeros transmitted so far, conditional upon representing the data as bits (one or zero). In a completely DC-free code, the number of transmitted ones and zeros should be subdivided to 50% respectively. Using the alternative code words according to the present invention, this is achieved, on average, using a code word 1 and a code word 2 inverse to it, if one memorizes the difference of the bit values transmitted so far, that is, if one forms a running total. For, if up to now more ones were transmitted, one would select the code data word having more zeros, or vice versa.

Now, in order to make possible a code recognition and subsequent code correction, a Hamming distance of at least three is required between two arbitrary code data words. This presupposes that, in the space for n (n of N) possible code words, 2n non-code data words are available. Now, if m data words (m of N) are to be transmitted, n has to be at least equal to 2m, in order to make possible the alternative code selection. Accordingly, 2m code data words and 2 times 2m non-code data words have to be accommodated in the same way in the code space, that is, 6m code data words and non-code data words have to be accommodated in such a way that a Hamming distance of 3 between two code data words is always ensured.

Now, if for the coding of a data word, that is, for generating a code data word having k bits (k of N), a number of 3 bits is additionally used for coding, the possibility comes about theoretically of satisfying these conditions in the 2^{(k+3)} code space. Therefore, for a data word having 4 bits, at least a 75% code redundancy (3 bits) is required.

However, in the practical execution, one is frequently thwarted by additional boundary conditions for the coding, such as coding that is true to EMC, having as few bit changes/level changes as possible in the code data word or at the code data word boundaries. The code redundancy may go still higher because of this. There may also possibly be control code words in addition to the code data words, which fulfill special functions and must not be confused with code data words. Therefore, codes having 100% code redundancy are also used, especially for short data words.

### SUMMARY OF THE INVENTION

The design approach according to the present invention, that continues these considerations, described in detail in the following text, is able to avoid the above-named disadvantages of the related art, and at the same time may offer the required properties at least for a part of the data, and especially achieve a desired, prespecifiable Hamming distance (in particular a Hamming distance of 2 or 3), in response to a clearly lower expenditure.

In order to transmit the means having no DC component, there exists a rule, according to the present invention, which specifies a selection of the code data word in the transmitter, especially in the first subscriber. If the receiver, especially the second subscriber, advantageously has the same data as the transmitter, it is also possible for it to decide whether an inverting of the code data word would have to be undertaken or not. For this, the receiver only has to be notified, according to the present invention, under which conditions the transmitter has performed the coding. If we assume that the receiver has not received all the data of the transmitter, because during a continuous transmission it has been switched in only later, or, in the case of interference, a part of the data was lost, then the receiver would not have all this information available to it.

Therefore, the crux of the present invention is the possibility of transmitting this information in addition to the data, especially using non-code data words.

Such non-code data words are usually required in order to characterize the beginning of a transmission, for instance, or to distinguish between the kind of the following data, and, in the case of a continuous transmission, also to make possible the synchronizing of the newly added receivers. Thus, for example, there are bus systems, that is, communications systems, in which the data are organized in so-called frames that begin with a preamble. This preamble has to differ from the code data words. If the coding criteria for the receiver are known, it no longer has to incorporate all code data words in the case of a required error detection or error correction, but only half. That way the required Hamming distance between the remaining code words is expediently maintained better, without increasing the code redundancy.

Thus, the present invention advantageously relates to a method for error handling in the transmission of coded data in the form of at least one data word via a communications system having at least two subscribers, a code word according to a specifiable cording rule being selected for the at least one data word; the data being represented as bits which are able to assume two different values, ones and zeros. In an expedient manner, in this context, a running digital sum, the so-called running digital sum RDS is formed in such a way that a summed difference of the total number of ones and the total number of zeros is formed at least through the data word, and this running digital sum RDS is transmitted from the first to the second subscriber, the second transcriber determining the running digital sum for the following code data word of the first subscriber and then comparing it to the one then being transmitted, an error being detected in response to a deviation. Furthermore, the transmitted running digital sum is stored in the receiver, and updated with each received data word, that is, the running digital sum is newly calculated after each data word, on the basis of the previous running digital sum and the number of ones and zeros in the data word that was just received. Provided no error occurs in the transmission, in the receiver, for each position of a data word, exactly the same information is present which the transmitter had during the coding of this data word corresponding to the coding rule. Now each code data word can be checked as to whether the selection of the code word is plausible or whether, under the present conditions, the inverted code data word should have been used. Not only the running digital sum is drawn upon for the checking of the plausibility, but also whether at the beginning of the received data word, according to the coding rule, a level change should take place for balanced code words (PV) and whether this level change is taking place (PE). This means that the decision for the current code data word is advantageously made a function of the current running digital sum rds and the coding rules. Because of the transmission and the constant updating, this RDS value is known to the receiver, that is, especially to a second subscriber, whereby the selection of the possible code data words may then be limited to about one half. It is therefore advantageously provided to transmit the RDS periodically, in particular, and to continue to process it on this basis in the receiver, i.e. especially in the second subscriber, until the next updating. Then, according to the present invention, using the newly received RDS value, the correctness of the current code data words can be confirmed with respect to the data correction that has already been undertaken, or, if applicable, an error may be detected in response to a deviation.

Besides the coded data, also at least one non-code data word is expediently transmitted between the first subscriber and the at least second subscriber, which is not coded according to the specifiable coding rule, and the running digital sum is transmitted at least as a part of the non-code data word.

In this context, in an expedient manner, as mentioned above, a code word or code data word is selected corresponding to the specifiable coding rule, which in each case corresponds to a first or a second code data word, which represented code data words that are inverted with respect to each other.

Corresponding to the specifiable coding rule, in an advantageous manner, the code data word is selected from a plurality, that is, at least two different code data word records.

In response to the detection of an error, an error signal is generated of the subscriber that has detected the error, and this error signal is transmitted at least to the subscriber by whom the error was transmitted.

In response to the detection of an error, in an expedient manner, the erroneous data are discarded as the error reaction, and the subscriber transmitting these receives a request signal to transmit these data again.

It is also advantageous that, besides the coded data, also at least one non-code data word is transmitted between the first subscriber and the at least second subscriber, which is not coded according to the specifiable coding rule, and the running digital sum is also formed through the non-code data word.

In a further expedient manner, according to the present invention, a correction of the error is undertaken in which, as a function of the running digital sum, that is, running digital sum RDS, the following RDS is ascertained again, and the erroneous data are replaced as a function of that.

A strategy specification for error handling advantageously takes place as a function of the number of errors. In this context, besides the error correction, the strategy can also provide that no error correction is to occur under prespecified assumptions, or that a correction of the error is undertaken in that the erroneous data word is replaced by a certain stipulated data word, or a certain correction data word is selected from the number of possible correction data words, that is, the data words that satisfy the coding rules while observing the RDS, which is then used further instead of the data word received and detected as being erroneous.

It is especially advantageous to represent the method according to the present invention within the scope of a computer program or a computer product having program code that is stored on a data carrier, the method being executed if the program is run in a computer-assisted communications system, as mentioned above. In this context, every possible data carrier may be used as the data carrier of the computer program product, such as ROM, CD-ROM, EPROM, EEPROM, flash EPROM, PROM, DVD, floppy disk, RAM etc. That is, the choice of a data carrier depends on the computer system on which the method is to run, but it has absolutely no limiting effect with respect to the present invention.

### BRIEF DESCRIPTION OF THE DRAWINGS

The present invention is elucidated in the following with reference to the figures and tables illustrated in the drawings. In this context

FIG. 1 shows a communications system having subscribers.

FIG. 1a shows a code generator according to the present invention, having an assignment according to rule 1b.

FIG. 2b shows schematically the conversion of an input code into an output code with the aid of a code generator that is designed as a decrementer.

FIG. 3a also shows a conversion using decrementers, here especially according to rule 5b.

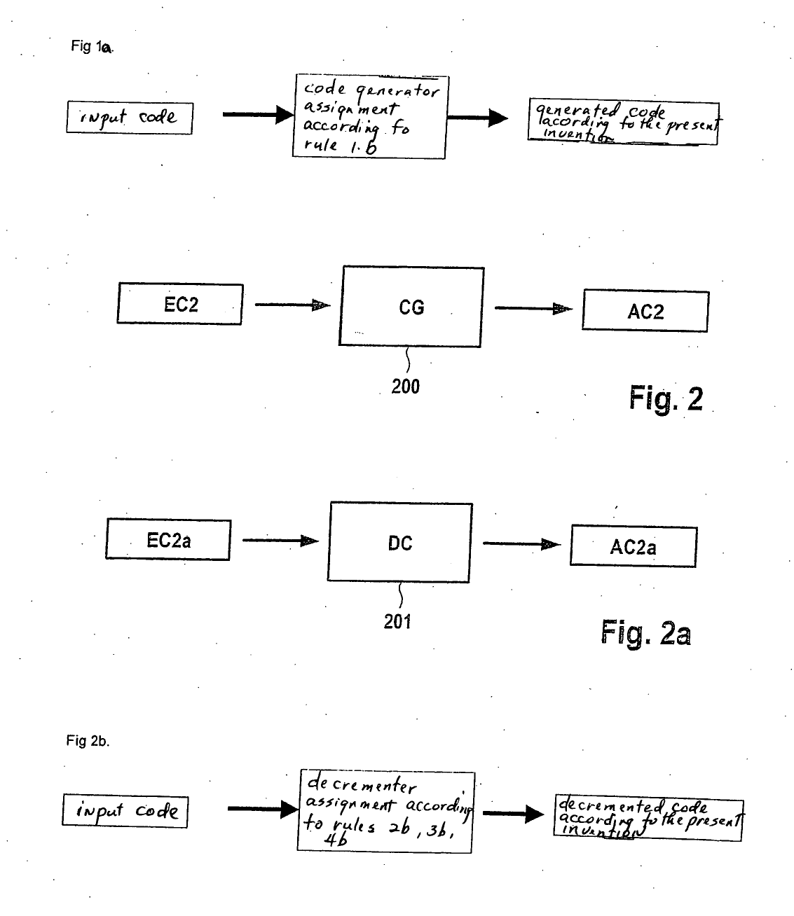

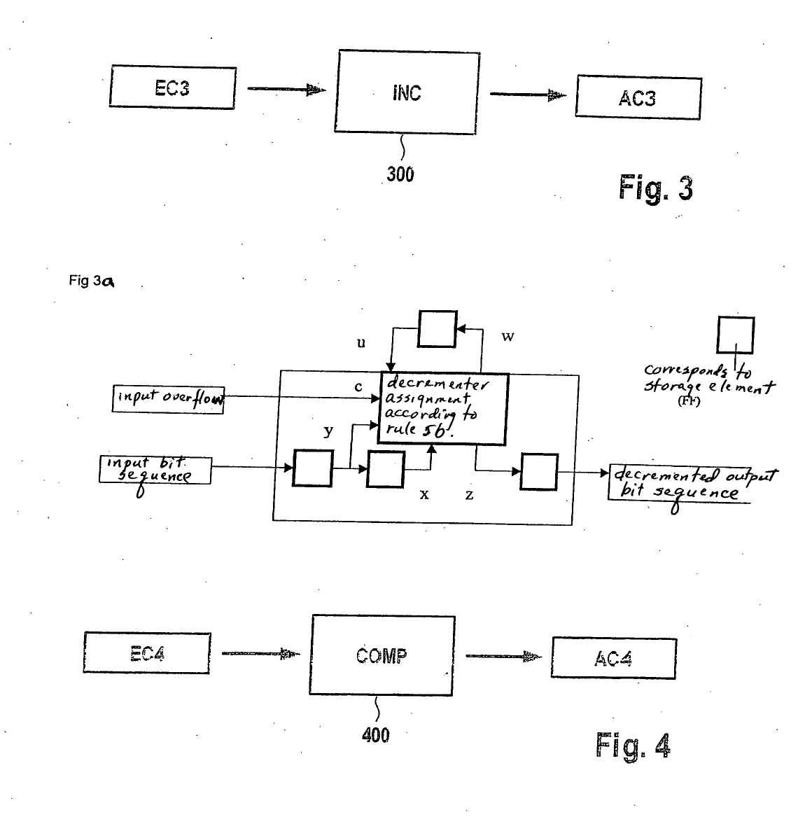

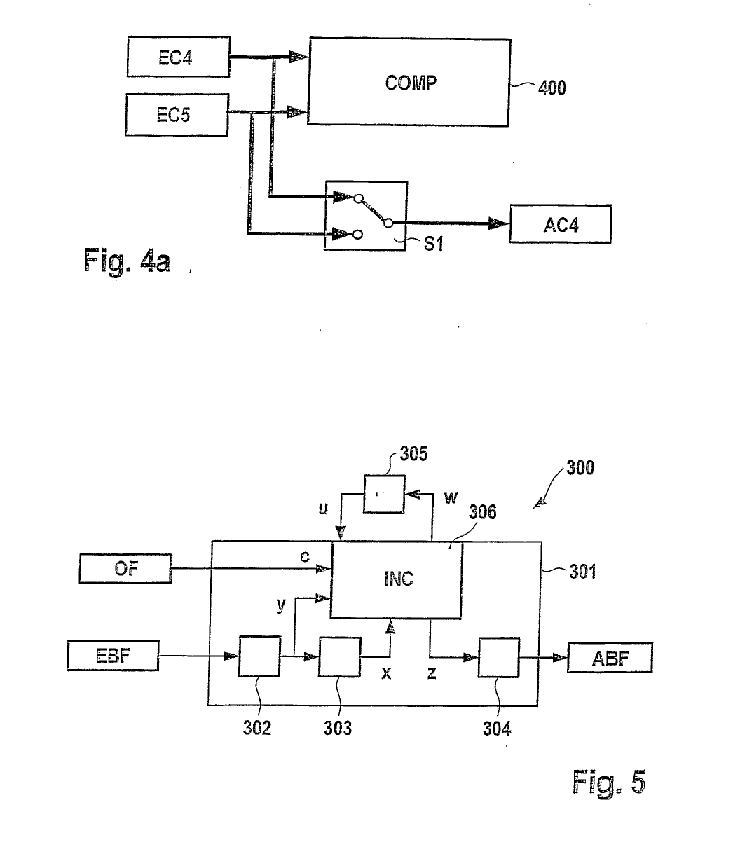

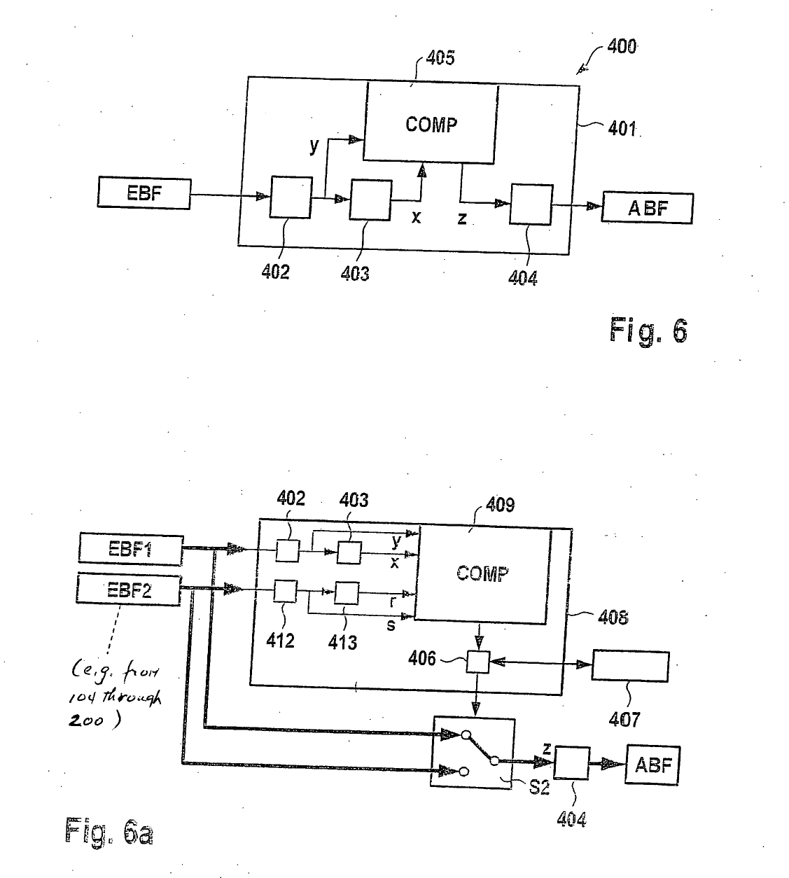

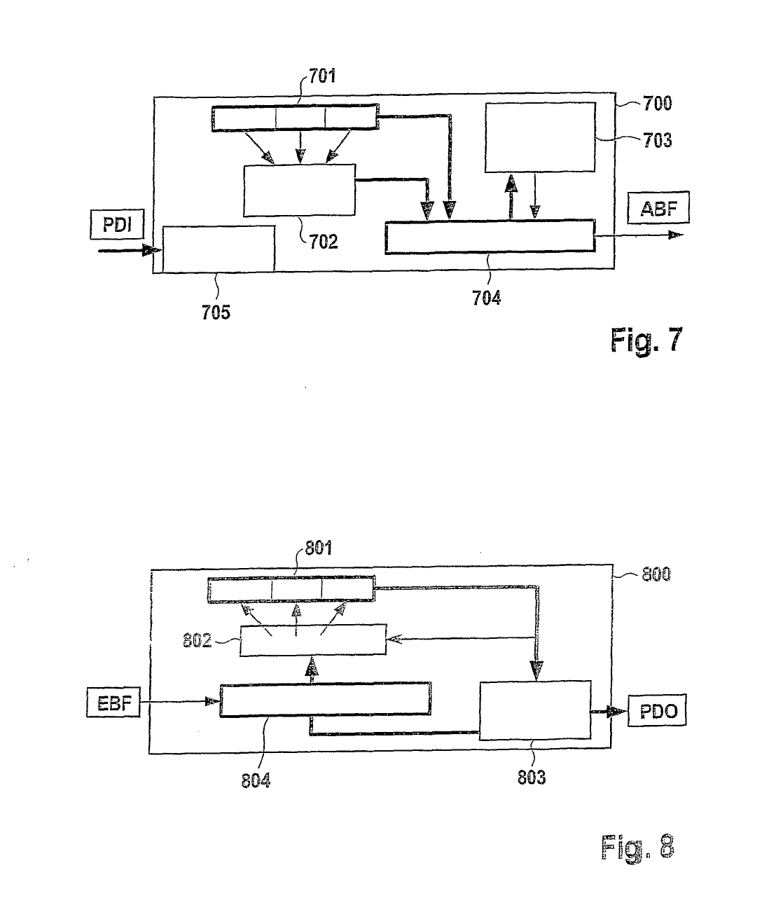

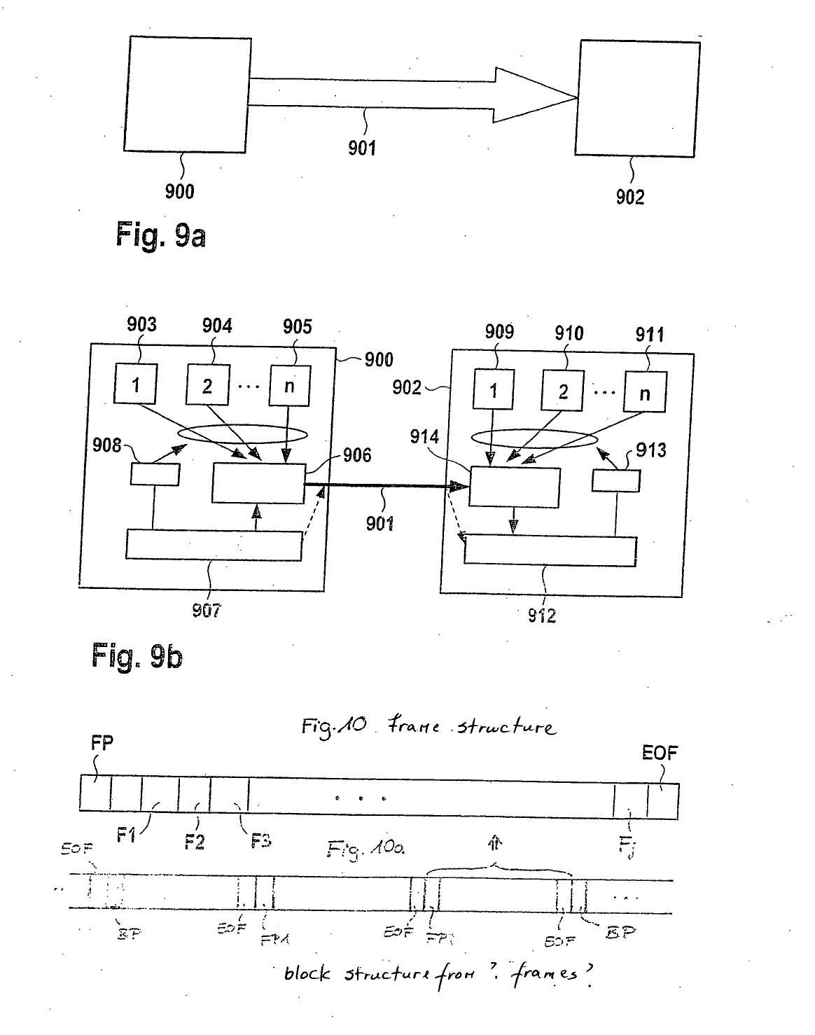

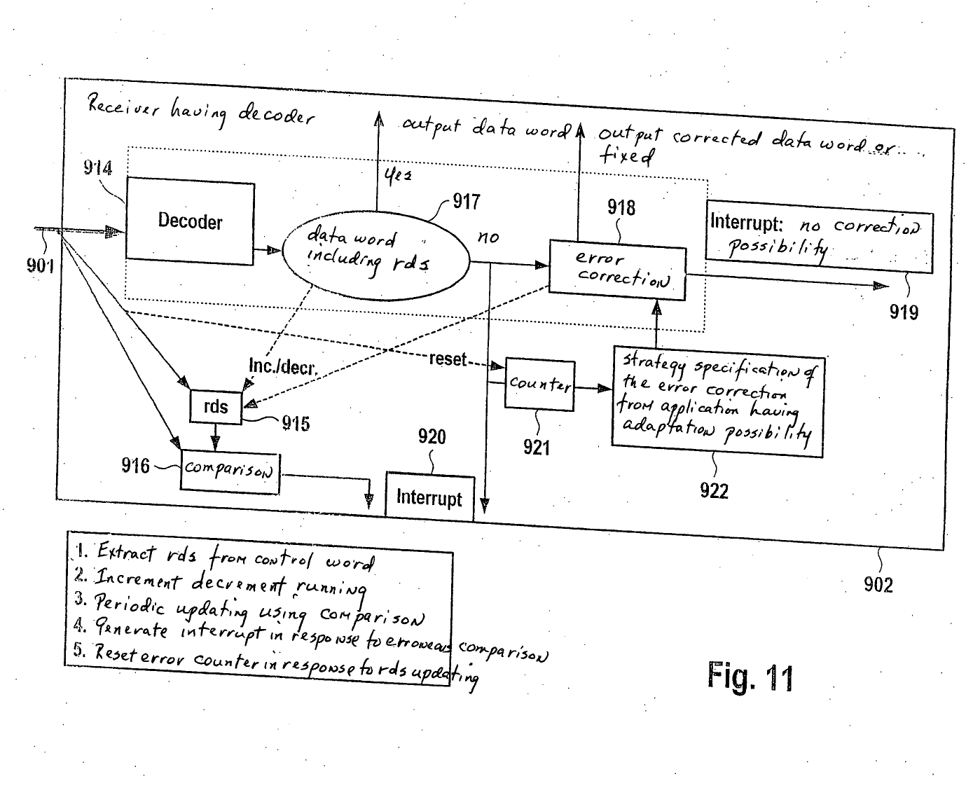

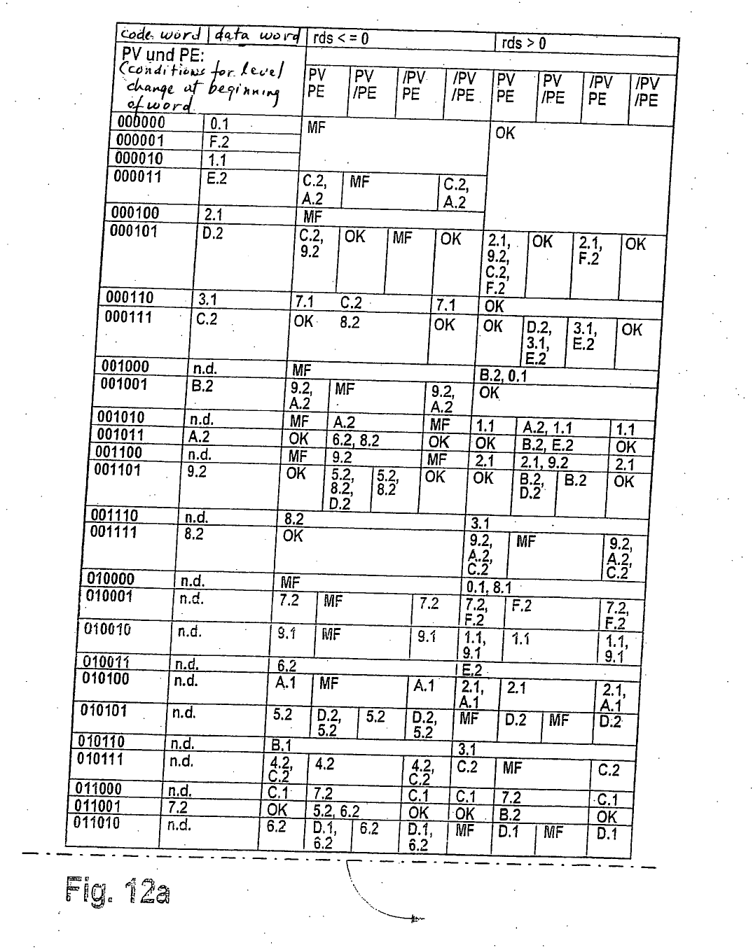

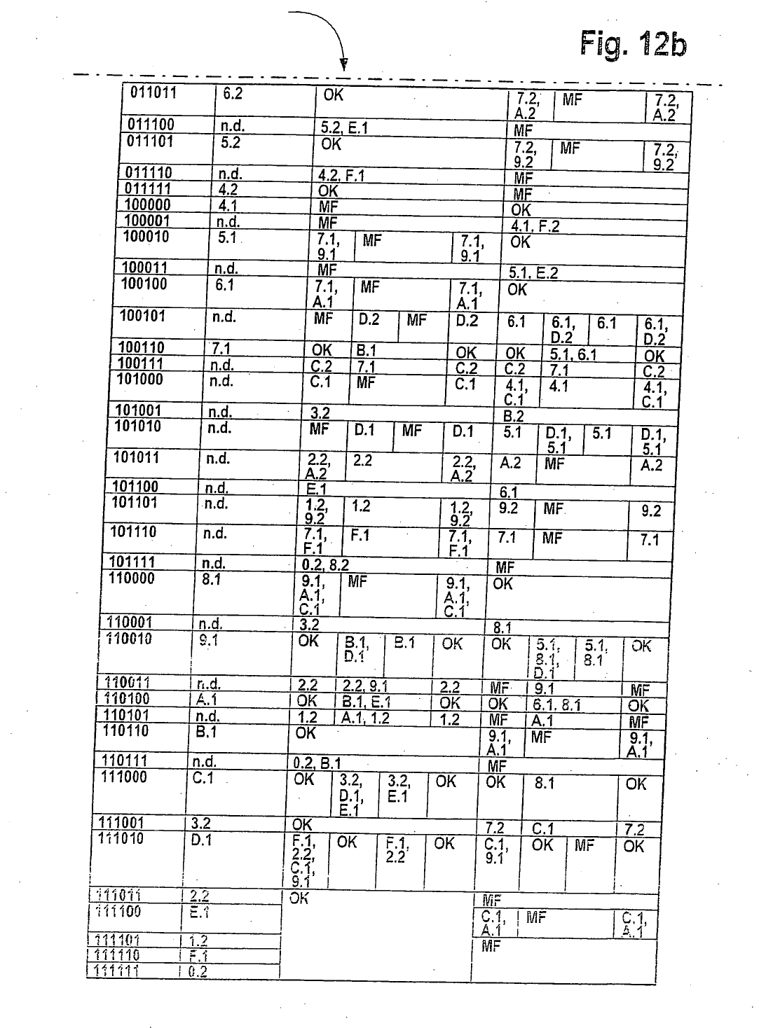

FIGS. 2, 2a, 3 and 4 as well as 4a show schematically the conversion of an input code to an output code with the aid of a code generator (FIG. 2), decoder—“direction of arrow reversed”, that is, EC2a corresponds to AC2 and AC2a corresponds to EC2 (FIG. 2a), an incrementer (FIG. 3) or a comparator (FIG. 4) as well as an arbitration unit having a comparator and a conversion unit (FIG. 4a).

A serial incrementer according to the present invention is shown in FIG. 5.

FIG. 6 shows a serial comparator according to the present invention.

FIG. 7 shows a serial transmitter as interface of, or to the communications system(s).

A corresponding serial receiver is shown in FIG. 8.

FIG. 9 shows once more in FIGS. 9a and 9b a code generator having alternative code data words and their transmission via a transmission route, as well as the corresponding receiver having a decoder and the recovery of the additional information from the RDS.

FIG. 10 shows an example of the frames having the different preambles according to the present invention.

Finally, FIG. 11 shows once more a decoder having error correction according to one prespecifiable strategy and adjustment capability.

Table 12 shows an example for a code correction rule for a partial correction at low code redundancy.

The present invention is now described below in detail, in light of the exemplary embodiments.

### DETAILED DESCRIPTION OF THE INVENTION

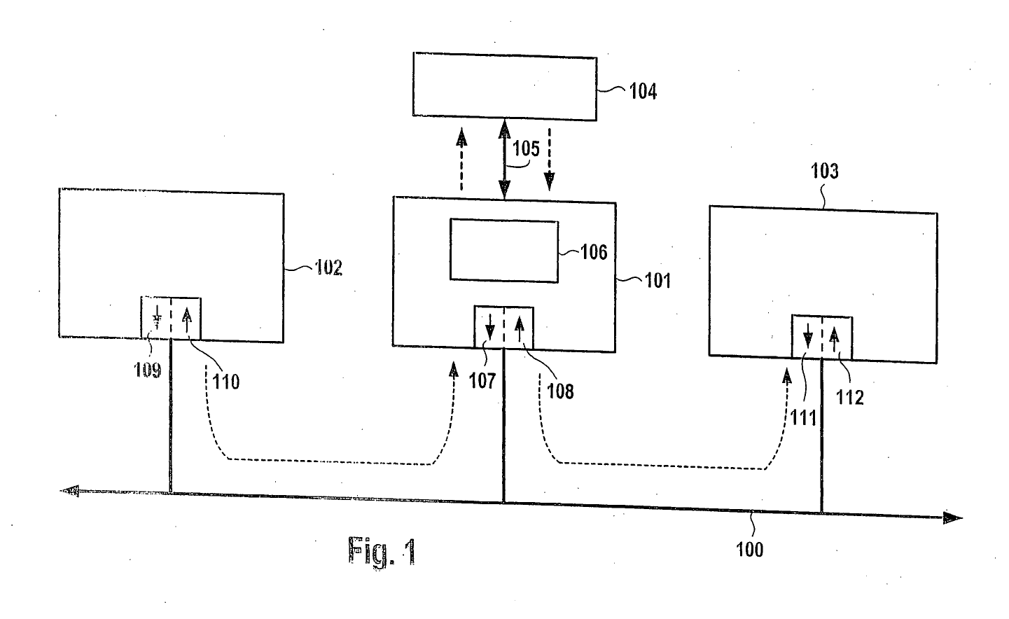

In this context, FIG. 1 shows communications system or bus system 100, having input interfaces 110, 108 and 112, that is, receivers or receiving modules, and output interfaces 109, 107, 111, that is, transmitters or sending modules. Using these transmitters and receivers, subscribers 101, 102 and 103 are connected to one another via communications system 100. !06 represents a processing unit which, according to the present invention, carries out the function of code generation and/or decoding and/or incrementing or decrementing and/or comparison or, more precisely, arbitrating. 104 represents a unit that is external to communications system 100, which is connected unidirectionally or bidirectionally to a subscriber, especially, in this case, to subscriber 101, via interface 105. This external unit 104 substitutes for the connection of additional devices, units or elements via interfaces or bus systems or communications systems to individual subscribers.

Now, it is intended here, during the transmission of the data via serial buses, that is, especially communications system 100, that especially an incrementing or an arbitration, that is, a comparison take place corresponding to the dotted transmission arrows during the transmission of the coded data. In the same way, however, it is also possible to input data to a subscriber 101 via an external subscriber 104, and then to forward these data in coded form, for example, in this case, to subscriber 103, again corresponding to the dotted arrows, or even to receive coded data from subscriber 102 to subscriber 101 and then to forward these data to an external subscriber 104 in decoded form. In this case, in particular, however, forwarding of the coded data is to take place on communications system 100, specifically taking into account incrementing, decrementing or comparison, or, more precisely, arbitrating, from subscriber 102 to subscriber 101 and then to subscriber 103.

In using a bifrequency code for coding, only two clock pulses of delay are required for serial incrementing if, for example, one transmits the lowest value bit of a data wors, that is, the LSB (least significant bit) first. In this context, it is only necessary to know which value the currently received code bit value and the previous one have, in order to determine the value to be output, that is, the value to be forwarded, of the respective bit.

According to the present invention, it is now provided to undertake a coding of two information bits using three code bits, in the following manner (rule 1):

| | Code | Value Assignment |
|---|---|---|
| Information Bits | Bits | (decimal/hexadecimal) |
| 00 | 000 | 0 |
| 01 | 100 | 1 |
| 10 | 110 | 2 |
| 11 | 111 | 3 |

Using a code redundancy of 50% it is achieved hereby that code words 010 and 101 are avoided, whereby the influence of the high spectral proportions in the code word is reduced. Whereas, from left to right, the values 2¹ or 2⁰ are assigned to the information bits, the weights of all code bits are 2⁰. In order to distinguish between the single bits in the code, in this case the nomenclature 2⁰⁽³⁾, 2⁰⁽²⁾ or 2⁰⁽¹⁾ is used, from left to right, according to the following rules 2, 3 and 4. This makes for a systematic coding rule, which also functions starting from any other code. If, for example, one has a one-hot coding, the four code words 0001, 0010, 0100 and 1000 are also assignable to the values 0, 1, 2 and 3, as in the case of a Gray code 00, 01, 11 and 10.

From one input code word or input data word EC2 as in FIG. 2, a code generation by code generator 200 CG into an output code word or output data word AC2 is always uniquely possible thereby. In the same way, in FIG. 2a, a decoding is shown of a data word EC2a into a data word AC2a by decoder DC 201. Now, this code according to the present invention is also suitable for carrying out a serial incrementing, as will be explained further on. According to rules 2, 3 and 4 (below), these single bits may now be distinguished from left to right according to the nomenclature 2⁰⁽³⁾, 2⁰⁽²⁾ or 2⁰⁽¹⁾, the incremented value being given and, correspondingly, overflow OF is created. This generated overflow OF is used for a serial coding as in rule 5, below, or shown in FIG. 5.

Rule 2

| for generating 2⁰⁽¹⁾ | incremented value of 2⁰⁽¹⁾ | |
|---|---|---|
| Code Bits | and | Overflow (OF) |
| 000 | 0 | 0 |
| 100 | 0 | 0 |
| 110 | 1 | 0 |
| 111 | 0 | 1 |

Rule 3

| for generating 2⁰⁽²⁾ | incremented value of 2⁰⁽²⁾ | |
|---|---|---|
| Code Bits | and | Overflow (OF) |
| 000 | 0 | 0 |
| 100 | 1 | 0 |
| 110 | 1 | 0 |
| 111 | 0 | 1 |

Rule 4

| for generating 2⁰⁽³⁾ | incremented value of 2⁰⁽³⁾ | |
|---|---|---|
| Code Bits | and | Overflow (OF) |
| 000 | 1 | 0 |
| 100 | 1 | 0 |
| 110 | 1 | 0 |
| 111 | 0 | 1 |

In that manner, from an input bit sequence or an input data word or an input code word EC3, according to FIG. 3, an output sequence AC3 is generated by incrementer INC 300. This is also possible, according to FIG. 4, within the scope of a comparison by comparator COMP 400, especially in the case of an arbitration from the input code sequence or input data word EC4 into output data word AC4 according to FIG. 4.

The change of incrementation to arbitration takes place, in this context, in the directional switchover, for the purpose that either the LSB, or least significant bit, the least valued bit, is evaluated first, which is required for incrementation, or, for a change in the direction of transmission, the most significant bit, MSB, that is, the highest valued bit is evaluated first, and consequently leads to the comparison, especially the arbitration. This will later be explained illustratively. Thus the code generator in FIG. 2, CG 200, carries out an assignment according to rule 1, the incrementer in FIG. 3 carries out an assignment according to rules 2, 3 and 4, in FIG. 2, generated output code AC2, according to the present invention, being generated from input code EC2, and in FIG. 3, incremented output code AC3, according to the present invention, being generated from already coded input code EC3.

The serial incrementation will now be explained in greater detail, in the light of FIG. 5, using respective values c or u, x, y, z, w according to rule 5:

Rule 5

| c or u | y | x | z | w |
|---|---|---|---|---|
| 0 | 0 | 0 | 0 | 0 |
| 0 | 1 | 0 | 0 | 0 |
| 0 | 1 | 1 | 1 | 0 |
| 0 | 0 | 1 | 1 | 0 |
| 1 | 0 | 0 | 0 | 1 |
| 1 | 1 | 0 | 1 | 0 |
| 1 | 1 | 1 | 0 | 1 |
| 1 | 0 | 1 | 0 | 1 |

FIG. 5 shows incrementer 300 as in FIG. 3 having an incrementing module 306 INC, an incrementing means 301 and a feedback branch which includes a flip-flop 305. Additional flip-flops are shown as 302, 303 and 304. These flip-flops may be implemented by any clock-pulse controlled memory elements. In this incrementer 300, that is incrementing means 301 having feedback, on the one hand, an input bit sequence EBF corresponding to a data word or data frame having several, at least two data words, as shown, is brought in, at the same time overflow OF, as shown, is taken into consideration and is converted to an incremented output bit sequence ABF or an output data word even an output data frame. For the serial incrementing of the code, for generating code bit x, information about subsequent code bit y is always required, if the transmission begins with the least significant bit, LSB, that is, with the lowest value bit of the bit sequence.

Therefore the code has to be forwarded delayed by at least one clock pulse. For the synchronization of the data bit sequence that is received and that is to be transmitted, in an advantageous way, in each case a flip-flop, that is 302 and 304, is inserted at the input and the output. The incrementation which takes place for the input overflow OF is c, for the intermediate overflow u, for the input bits x and y according to rule 5, for the output bit z, as well as for the generated intermediate overflow w. With that, it is now possible also to compose even larger code words while possibly using rule 1 several times for, in each case, parts of the code word, or directly to insert even parts without further coding, specifically the information bits in rule 1, as is explained in more detail in rule 6.

Rule 6

| Information Bits | Code Bits | Value Assignment (hexadecimal) |
|---|---|---|
| 00 00 | 000 000 | 0 |
| 00 01 | 000 100 | 1 |
| 00 10 | 000 110 | 2 |
| 00 11 | 000 111 | 3 |
| 01 00 | 100 000 | 4 |
| 01 01 | 100 100 | 5 |
| 01 10 | 100 110 | 6 |
| 01 11 | 100 111 | 7 |
| 10 00 | 110 000 | 8 |
| 10 01 | 110 100 | 9 |
| 10 10 | 110 110 | A |
| 10 11 | 110 111 | B |
| 11 00 | 111 000 | C |
| 11 01 | 111 100 | D |
| 11 10 | 111 110 | E |
| 11 11 | 111 111 | F |

Compared to the incrementation of a block code (which, as was shown before, cannot be done serially) there comes about, using the system as in FIG. 5, always only a delay by 3 clock pulses even in the case of rule 6, since the two code parts are processed one after the other. The code of rule 6 processes a half byte, that is, four information bits (=1 nibble), as the information word. The code redundancy amounts to 50%. It is, however, a disadvantage in this case that, by alignment of the values 0 or F, larger blocks may be created without level change and the code has no DC component.

To remove this disadvantage, a code is first selected according to rule 7, which has only 25% code redundancy, when a part of the original code is taken over unchanged.

Rule 7

| Information Bits | Code Bits | Value Assignment (hexadecimal) |
|---|---|---|
| 00 00 | 000 00 | 0 |
| 00 01 | 000 01 | 1 |
| 00 10 | 000 10 | 2 |
| 00 11 | 000 11 | 3 |
| 01 00 | 100 00 | 4 |
| 01 01 | 100 01 | 5 |
| 01 10 | 100 10 | 6 |
| 01 11 | 100 11 | 7 |
| 10 00 | 110 00 | 8 |
| 10 01 | 110 01 | 9 |
| 10 10 | 110 10 | A |
| 10 11 | 110 11 | B |
| 11 00 | 111 00 | C |
| 11 01 | 111 01 | D |
| 11 10 | 111 10 | E |
| 11 11 | 111 11 | F |

In order to form the code according to rule 7 to have no DC component, another inverting bit, which first of all has a value of 0, is fitted in below the least significant bit, that is, the lowest value bit. Then, the inversion of the entire code word, that is, including the inverting bit, does not lead to a change in the value. Thus, there are two code words having the same value, which begin with different bit values. In the case of a sequence of zeros, one may then alternatingly transmit the code word 000000 and 111111. Doing this yields a complete compensation of the DC components, that is, the same number of ones and zeros according respectively to two code words. Furthermore, at each beginning of a code word there is a change of level, which may be used for a timing recovery using PLL. From this, there now comes about rule 8, as shown below.

Rule 8

| | Code | Inversion | Value Assignment |
|---|---|---|---|
| Information Bits | Bits | Bits | (hexadecimal) |
| 00 00 | 000 00 | 0 | 0 |
| 00 01 | 000 01 | 0 | 1 |
| 00 10 | 000 10 | 0 | 2 |
| 00 11 | 000 11 | 0 | 3 |
| 01 00 | 100 00 | 0 | 4 |
| 01 01 | 100 01 | 0 | 5 |
| 01 10 | 100 10 | 0 | 6 |
| 01 11 | 100 11 | 0 | 7 |
| 10 00 | 110 00 | 0 | 8 |
| 10 01 | 110 01 | 0 | 9 |
| 10 10 | 110 10 | 0 | A |
| 10 11 | 110 11 | 0 | B |
| 11 00 | 111 00 | 0 | C |
| 11 01 | 111 01 | 0 | D |
| 11 10 | 111 10 | 0 | E |
| 11 11 | 111 11 | 0 | F |

Rule 9 below now shows all data words with their two possible variants.

Rule 9 (for transmission using LSB first):

| | | | Value Assignment |
|---|---|---|---|
| Information Bits | Code Word 1 | Code Word 2 | (hexadecimal) |
| 00 00 | 000 000 | 111 111 | 0 |
| 00 01 | 000 010 | 111 101 | 1 |
| 00 10 | 000 100 | 111 011 | 2 |
| 00 11 | 000 110 | 111 001 | 3 |
| 01 00 | 100 000 | 011 111 | 4 |
| 01 01 | 100 010 | 011 101 | 5 |
| 01 10 | 100 100 | 011 011 | 6 |
| 01 11 | 100 110 | 011 001 | 7 |
| 10 00 | 110 000 | 001 111 | 8 |
| 10 01 | 110 010 | 001 101 | 9 |
| 10 10 | 110 100 | 001 011 | A |
| 10 11 | 110 110 | 001 001 | B |
| 11 00 | 111 000 | 000 111 | C |
| 11 01 | 111 010 | 000 101 | D |
| 11 10 | 111 100 | 000 011 | E |
| 11 11 | 111 110 | 000 001 | F |

Rule 9 represents a preferred exemplary embodiment for transmitting the code with the LSB first. If the number of ones is constantly added during the transmission, and the number of zeros subtracted from it, one obtains the RDS, the running digital sum, which gives information as to whether more ones or zeros are being transmitted. Using code words that include a different number of ones and zeros, one may influence the RDS by the selection between code word 1 and code word 2. Under favorable circumstances one tries to arrive at the value RDS=0, and thereby to form the code with no DC component, on average. However, in this context, slight deviations from this rule are also possible and conceivable, if one either wishes to force a level change between the code words, e.g. because of the timing recovery, that is, the PLL, or avoid it because of the frequency spectrum.

If the input code word increments in the incrementer according to rule 9, that is, from the point of view of the value, this may lead to a change in the RDS value according to the incremented data value compared to the original value. In this context, for the incremented data word to be transmitted, there is not the possibility of selecting the inverse code word, because the inverting bit has to be sent before the entire code word has been received. A correction may be made in this situation by subsequent non-data code words which, for example, may characterize the beginning of a data frame, if a selection from several values having different RDS values is admissible at an equal meaning with respect to the frame characterization.

The incrementing according to rules 2, 3, 4 and 5 is only described for code words 1 according to rule 9. For code words 2, all zeros (0) are to be replaced by ones (1), and, in reverse, the ones by zeros. Then the same rules apply.

The code described in the preceding paragraph according to rule 9 is particularly suitable for serial incrementing (in conjunction with LSB first) or for arbitration (in conjunction with MSB first). This code is less suitable for decrementing, because there then exists no rule corresponding to rule 5 for this code which, independently of the position in the code, determines the new code bit (to be transmitted) from input bits x and y and from overflow bits c and u. Therefore, especially for decrementing, the following generating rule 1.b is used instead of rule 1:

| Piece | | |
|---|---|---|
| of | | Value |
| Data | Coding rule 1.b | (hex) |
| 00 | 000 | 0 |
| 01 | 001 | 1 |
| 10 | 011 | 2 |
| 11 | 111 | 3 |

The following rules 2b, 3b or 4b are obtained for the decrementing on the basis of code 1.b instead of rules 2, 3 and 4 for the incrementing on the basis of rule 1:

(Rule 2b):

| For generating 2^{0′} | | |
|---|---|---|
| Code Bits | decremented value of 2^{0′} and | Overflow |
| 000 | 1 | 1 |
| 001 | 0 | 0 |
| 011 | 1 | 1 |
| 111 | 1 | 1 |

(Rule 3b):

| For generating 2^{0″} | | |
|---|---|---|
| Code Bits | decremented value of 2^{0″} and | Overflow |
| 000 | 1 | 1 |
| 001 | 0 | 0 |
| 011 | 0 | 0 |
| 111 | 1 | 1 |

(Rule 4b):

| For generating 2^{0′′′} | | |
|---|---|---|
| Code Bits | decremented value of 2^{0′′′} and | Overflow |
| 000 | 1 | 1 |
| 001 | 0 | 0 |
| 011 | 0 | 0 |
| 111 | 0 | 0 |

The generated overflow is used in the case of serial coding (see rule 5b). The advantage in this code is that the output value and the overflow are identical in the case of decrementing, and otherwise the overflow is 0.

For the serial decrementing of the code, in order to generate code bit x, information on the next following code bit y is required (if the transmission is begun with the LSB). Therefore, as in the case of serial incrementing, the code has to be forwarded delayed by at least one clock pulse. For the synchronization of the data bit sequence that is received and that is to be transmitted, in an advantageous way, in each case a flip-flop is inserted at the input and the output. Decrementing takes place for input overflow c, intermediate overflow u, input bits x and y according to rule 5b for output bit z as well as for generated intermediate overflow w (FIG. 3a):

Rule 5b

| c or u | y | x | z | w |
|---|---|---|---|---|
| 0 | 0 | 0 | 0 | 0 |
| 0 | 0 | 1 | 1 | 0 |
| 0 | 1 | 0 | 0 | 0 |
| 0 | 1 | 1 | 1 | 0 |
| 1 | 0 | 0 | 1 | 1 |
| 1 | 0 | 1 | 0 | 0 |
| 1 | 1 | 0 | 1 | 1 |
| 1 | 1 | 1 | 1 | 1 |

However, the code according to the present invention may also be used for arbitration purposes that is, for comparison purposes. Thus the described code, especially according to rule 9 may also be used for arbitration purposes having variable priorities. For this, it is necessary to begin with the transmission of the highest value bit, that is, the most significant bit, whereas for incrementing, as was mentioned before, one begins with the least significant bit, that is, the LSB, the lowest valued bit. However, the inverting bit is transmitted first even then (rule 10).

Rule 10 for transmitting with MSB first:

| | | | Value Assignment |
|---|---|---|---|
| Information Bits | Code Word 1 | Code Word 2 | (hexadecimal) |
| 00 00 | 0 000 00 | 1 111 11 | 0 |
| 00 01 | 0 000 01 | 1 111 10 | 1 |
| 00 10 | 0 000 10 | 1 111 01 | 2 |
| 00 11 | 0 000 11 | 1 111 00 | 3 |
| 01 00 | 0 100 00 | 1 011 11 | 4 |
| 01 01 | 0 100 01 | 1 011 10 | 5 |
| 01 10 | 0 100 10 | 1 011 01 | 6 |
| 01 11 | 0 100 11 | 1 011 00 | 7 |
| 10 00 | 0 110 00 | 1 001 11 | 8 |
| 10 01 | 0 110 01 | 1 001 10 | 9 |
| 10 10 | 0 110 10 | 1 001 01 | A |
| 10 11 | 0 110 11 | 1 001 00 | B |
| 11 00 | 0 111 00 | 1 000 11 | C |
| 11 01 | 0 111 01 | 1 000 10 | D |
| 11 10 | 0 111 10 | 1 000 01 | E |
| 11 11 | 0 111 11 | 1 000 00 | F |

A circuit for this comparison or arbitration is shown with comparator 400 according to FIG. 6 and FIG. 6a. It shows a comparator module 401 or 408 having the actual comparator 405 or 409 COMP, only in this case respectively two flip-flops 402, 403 or 412, 413 being required for the delay and synchronization of the two input bit sequences that are to be compared, which here too are preparable by any clock pulse-controlled storage elements. For the arbitration of the code, to make the decision on the transmission of code bit x or r in FIG. 6 or FIG. 6a in the general case, the information on the next following code bit y or s is again required. In this case, this is true if the transmission is begun with the MSB, that is, the most significant bit. Here too, therefore, the code has to be forwarded delayed by at least one clock pulse. For the synchronization of the data bit sequence that is received and that is to be transmitted, in an advantageous way, here too in each case a flip-flop 402 and 412, is inserted at the input and the output. Following the rule according to the present invention, from the input bits x and y or r and s, output bit z and consequently the selection of the input bit sequence EBF and EBF 1 or EBF2 and its conversion into output bit sequence ABF are performed within the scope of the arbitration. In this context, the comparator decision remains stored, in FIG. 6a, in memory element 406, until the decision is reset using a control unit 407. The comparator decision, once taken, may also be used in the following course of the data transmission, in order purposefully to undertake an additional switchover between the two input bit sequences. To do this, the currently taken comparator decision is transmitted to control unit 407, and is stored there. With the aid of this information, memory element 406 may be set and reset as desired by 407. In FIG. 6a there is furthermore provided a switch or switchover unit S2, which makes possible a change between input bit sequences EBF1 and EBF2 for an additional sequence, as described for FIGS. 6 and 6a.

FIG. 4a shows this change, this circuit using switch or switchover unit S1 for two input data words EC4 and EC5 for a comparator 401 according to FIG. 4 and an output data word AC4.

Incrementing or decrementing and arbitrating cannot occur simultaneously in a data word. However, within the scope of circumstances in which there is to be arbitration or incrementation and decrementation, a change in the sequence of transmission or sending may be undertaken. As a function of the transmitting direction there now comes about for rule 9 in the exemplary embodiment, specifically LSB first, and therewith the incrementing variant or MSB first with rule 10, and therewith the arbitrating variant. In this context, the first two bits of the piece of data are converted according to the two-bit coding into three-bit coding, and the second two bits, that is, bit 3 and bit 4 of the piece of data are taken over uncoded. At the same time, the inversion bit, that is, the bit that indicates whether the inverted or the non-inverted variant is involved, is added according to rule 9 as least significant bit in dode word 1 and code word 2, that is, all the way over to the right. Now, with regard to the MSB side, the situation is similar, so that the first two bits of the piece of data are coded, in each case in the middle block of three, into the triple bits, and the two last bits of code words 1 or 2 are simply transferred as bit 3 and bit 4 of the piece of data. However, in this case, the bit indicating the inversion is added as highest value bit, MSB, in each case at the left at code word 1 and code word 2 of the MSB variant.

As an example for illustration, in this case, again a bus is suitable in which, as in the MOST bus, the data are transmitted within the framework of fixed length, depending on the frame position, a change in the transmission sequence or the transmission direction being able to be undertaken. If, for example, the transmitting of a control frame is to be decided after a prioritization, in that the received priority is compared with its own priority, it is advantageous to transmit the MSB first. With that, as shown in FIG. 6a, one may perform a direct switchover. If, by contrast, the network position is to be determined and at the same time (without intermediate storing) is to be forwarded to the following node, the corresponding control byte has to be sent with the LSB first, in order to be able to increment serially (according to FIG. 5). Since the control frame information having the necessity for an arbitration is always transmitted at a fixed place in the data frame, that is to the frame, at MOST always the 61^{st} and 62^{nd} byte, in this case, advantageously, the transmission sequence is changed to MSB first as a function of the word counter or byte or bit counter within a data frame, that is, a counter. Everywhere at the byte positions in the frame where incrementing or decrementing could be necessary, the transmission sequence is switched back to LSB first. At positions at which neither an arbitration by the comparison of several bits is required, nor incrementation or decrementation is required, the transmission sequence is unimportant, and may be freely chosen according to other criteria.

In this context, one should note, and not only for the MOST case, that according to the present invention, the inversion bit is always transmitted first, that is, independently of whether beginning with the LSB or the MSB.

With reference to above-named rule 1, which represents the most favorable systematic design approach variant for the coding according to the present invention of two information bits into three code bits with regard to EMC properties, the following variants for rule 1 are also conceivable and possible.

| Piece | | | |
|---|---|---|---|
| of | | | Value |
| Data | Coding rule 1.b | Coding rule 1.c | (hex) |
| 00 | 000 | 000 | 0 |
| 01 | 001 | 010 | 1 |
| 10 | 011 | 110 | 2 |
| 11 | 111 | 111 | 3 |
| Piece | | | |
| of | | | Value |
| Data | Coding rule 1.d | Coding rule 1.e | (hex) |
| 00 | 000 | 000 | 0 |
| 01 | 100 | 011 | 1 |
| 10 | 110 | 110 | 2 |
| 11 | 011 | 111 | 3 |

In this context, the coding rule according to 1b has the same advantages for the case of decrementing compared to rule 1 for incrementing. Here, too, there is present a systematic code in which each code bit may be assigned a value 2⁰. However, let us first of all explain in more detail the case of incrementing.

Corresponding to the preferred embodiment variant as in rule 1, or rather rules 9 and 10 developed from it, special transmission modules and receiving modules according to FIG. 7 and FIG. 8, that is, transmitters and receivers, may now be shown. FIG. 7 shows a serial transmitter, in which parallel data input, PDI, that is, for example, n bits are input in parallel into a register and code generator 705. In this example, n is preferably 4. Using a shift register 704, which is able to pack k bits, where k is preferably 6, an output bit sequence ABF may then be output to communications system 100. In this context, transmission module 700 includes optional elements 701 to 703, which will be explained. During the switchover between LSB and MSB first, that is, between incrementation and arbitration as a function of a word counter or counter if, for example, the transmission sequence is changed, such a counter 701 is required. At the same time, a control circuit 703 is required which particularly controls the inversion control, that is, the specification of the inverting bit corresponding to LSB and MSB according to rule 9 or 10. At the same time, monitoring of the RDS value may take place, or rather specification, by this circuit 703. Block 702 is used for inserting non-data words, which will be explained later. Similarly, in block 703 the function of the D control may be implemented, which will be explained in greater detail below.

Corresponding to transmission module 700, 800 in FIG. 8 shows a receiving module or serial receiver. In this exemplary embodiment, an input bit sequence EBF is supplied to a shift register 804 having k bits, here too preferably k=6. 803 represents the corresponding decoding module, especially having a register. According to the present invention, in order to emit a parallel bit sequence, that is, PDO of, for instance, n bits, with n=4, use is again made of the switchover, and, for example, the transmitting sequence is changed as a function of the word counter, and here too this counter 801 is optionally installed. Block 802 is used to detect the non-data words, that is, for decoding them, whereby a partial setting of the counter may take place, as will be explained later. This means that transmitter and receiver according to FIG. 7 and FIG. 8, according to the present invention, are able to undertake the complete coding and decoding.

The non-data words, already mentioned in connection with elements 702 and 802 will now be explained in greater detail. The code space for 6 code bits permits 2⁶=64 different possibilities, of which, according to rule 9 only 32 data code words are assigned. For some application cases it is meaningful to agree to have some non-data code words or non-data words having additional information, especially having control data, be used for control purposes. Using this, one may, for example, indicate the beginning of a transmission or cause other control functions, such as transition into another operating mode, as well as initiate the transmission of special sequence information. These non-data code words may be a block preamble or a data frame preamble, that is, a frame preamble, for instance. The frame preamble only indicates the beginning of a frame. If several frame preambles are allowed, then, by the selection of the variant, various additional data may be transmitted. Such additional information may be the RDS value under which the current coding was undertaken. Examples of this are given in Table 1, this table not being final.

TABLE 1

| Control Sequence | Code Word 1 | Code Word 2 |
|---|---|---|
| Block Preamble | 101 010 | 010 101 |
| Frame Preamble (rds before code word | 101 110 | 010 001 |
| was 0) | | |
| Frame Preamble (rds before code word | 011 110 | 100 001 |
| was −2/+2 | | |
| Frame Preamble (rds before code word | 011 000 | 100 111 |
| was +4/−4) | | |
| Frame Preamble (rds before code word | 101 000 | 010 111 |
| was +6/−6) | | |
| Frame Preamble (rds before code word | 010 010 | 101 101 |
| was +8/−8) | | |

The bit sequence 010101 or, inverted, 101010, plays a special role in the case of the non-data code words. This bit sequence is used for synchronization, and should not be created unintentionally, even by the combination of two data words one after the other. Without an additional condition, the sequence according to rule 9 is created, for example, by the connection of data words D (code word 1) according to 4, 5, 6 or 7 (from code word 1): 111010 100xx0 beginning at a transmission of LSB, a change of level between these two data words being provided by the RDS rule. The generation of this bit pattern by a combination of data code words is avoided if, while ignoring the RDS rule, it is always seen to in the transmission of a D that no change in level takes place. In the above example, according to rule 9, one obtains from this the bit sequence 000101 100xx0, and the selected bit sequence cannot be created. Under certain circumstances, this may lead to an increase in DC proportion, for a short period. However, it is impossible that the multiple successions of the transmissions of D leads to a steady increase of RDS, because then, always exactly between code word 1 and code word 2 rule 9 is appropriately changed. If, in addition, one takes care that, in the case of a code word following all the code words subsequent to the value D, having a balanced number of zeros and ones (7, 9, A, C and non-data code words) a level change always takes place (as long as an unbalanced code word does not interrupt this rule), then the RDS is not summed up even in case a data value D is transmitted again, since in that case the other code word may be usable by D, and is even used, of necessity, according to the above rule. A special control unit in the transmitter controls the emission of data word D, which may be implemented in FIG. 7, in block 703. An additional rule is that when RDS=0, the RDS value is increased, so that RDS does not negatively tend to zero, and this gives it single-valuedness.

Under these boundary conditions, the transmission of the special code word 010101 and its inversion permits the triggering of special control signals in the receiver, which lead to a selected system state. That may, for instance, be the setting of a counter in the receiver, such as by block 802 in counter 801, in FIG. 8. If non-data code words or non-data words are permitted only at regular points in time, since, for example, they mark the beginning of a data frame having constant length, it also makes sense to permit all other non-data words only at known positions between two of these special code words. Then these code words cannot be mistaken for data words or, in the case of patterns that are formed from two successive data words and that agree with the bit sequence of the non-data code word, they cannot be mistaken for this special control signal. Using this, it is also possible in a limited way to implement error detection. Besides the code variants shown that have preferred variants according to rules 9 or 10, additional components or compositions of rule 1, that is, a multiple use of this rule, and direct binary coding is also possible in several ways. The code of the preferred exemplary embodiments avoids the dominant spectrum of a Biphase Mark Coding. It is without DC component on average and has a mximum run length typically of 13 or 14 (depending on the coding rule), if retroactive data changes by incrementing or decrementing are not taken into consideration. However, these data changes may be compensated for again by subsequent non-data code words. Preferably, non-data words are, for instance, 101010, 001110, 001100, 011110, 011100, according to the table, as well as the incerse values of these, but, in principle, all other non-data words may also be used.

The rules for avoiding the bit sequence 101010 by assembling coded data words according to the exemplary embodiment of rule 9 have to be appropriately adapted in response to a switchover of incrementing and arbitrating:

If a change is made from LSB first to MSB first, there exists no rule with regard to inverting besides reducing the RDS value in the absolute quantity.

Between two MSB first values, a level change (instead of before “D”) to after hexadecimal value “A” has to be avoided.

For all balanced code words after an “A” there is no rule in this case, since “A” itself is balanced (no RDS value change with A, whereby no rule for indirectly successive “A”'s is required.

For a transfer from MSB first to LSB first a level change should generally be prevented if the last 3 bits were alternating (according to 2, 6, A, D).

For a following “D”, the same conditions apply as otherwise, that is, no level change.

For the coding of a data word made up of more than 2 bits, the decision may further be made as to whether all bit pairs are transferred according to rule 1 or 1b coded or which bit pairs are transferred uncoded. In rule 9 it was the 2 LSB's of a 4 bit data word which were to be coded according to rule 1, while the 2 MSB's were transferred directly. The opposite way is possible in exactly the same manner according to rule 9a, in which the LSB's are transferred directly and the MSB's are coded according to rule 1:

Rule 9a: (preferable exemplary embodiment at original coding
according to rule 1 and exchange [transposition] of the
sequence of the coded data bits)

| LSB first | | | MSB first | | |
|---|---|---|---|---|---|
| Information | Code | Code | Value Assignment | | |
| Bits | Word 1 | Word 2 | (hexadecimal) | | |
| 00 00 | 00 000 0 | 11 111 1 | 0 | 0 00 000 | 1 11 111 |
| 01 00 | 00 100 0 | 11 011 1 | 1 | 0 00 100 | 1 11 011 |
| 10 00 | 00 110 0 | 11 001 1 | 2 | 0 00 110 | 1 11 001 |
| 11 00 | 00 111 0 | 11 000 1 | 3 | 0 00 111 | 1 11 000 |
| 00 01 | 01 000 0 | 10 111 1 | 4 | 0 01 000 | 1 10 111 |
| 01 01 | 01 100 0 | 10 011 1 | 5 | 0 01 100 | 1 10 011 |
| 10 01 | 01 110 0 | 10 001 1 | 6 | 0 01 110 | 1 10 001 |
| 11 01 | 01 111 0 | 10 000 1 | 7 | 0 01 111 | 1 10 000 |
| 00 10 | 10 000 0 | 01 111 1 | 8 | 0 10 000 | 1 01 111 |
| 01 10 | 10 100 0 | 01 011 1 | 9 | 0 10 100 | 1 01 011 |
| 10 10 | 10 110 0 | 01 001 1 | A | 0 10 110 | 1 01 001 |
| 11 10 | 10 111 0 | 01 000 1 | B | 0 10 111 | 1 01 000 |
| 00 11 | 11 000 0 | 00 111 1 | C | 0 11 000 | 1 00 111 |
| 01 11 | 11 100 0 | 00 011 1 | D | 0 11 100 | 1 00 011 |
| 10 11 | 11 110 0 | 00 001 1 | E | 0 11 110 | 1 00 001 |
| 11 11 | 11 111 0 | 11 000 1 | F | 0 11 111 | 1 00 000 |

direction of transmission

In the same way, especially in the selection of decrementing possibilities, additional coding rules are possible (rules 9b 9c):

Rule 9b (with exchange of sequence of the uncoded data bits and
coding according to rule 1.b)

| LSB first | | | MSB first | | |
|---|---|---|---|---|---|
| Information | Code | Code | Value Assignment | | |
| Bits | Word 1 | Word 2 | (hexadecimal) | | |
| 00 00 | 00 000 0 | 11 111 1 | 0 | 0 00 000 | 1 11 111 |
| 01 00 | 00 001 0 | 11 110 1 | 1 | 0 00 001 | 1 11 110 |
| 10 00 | 00 011 0 | 11 100 1 | 2 | 0 00 011 | 1 11 100 |
| 11 00 | 00 111 0 | 11 000 1 | 3 | 0 00 111 | 1 11 000 |
| 00 01 | 01 000 0 | 10 111 1 | 4 | 0 01 000 | 1 10 111 |
| 01 01 | 01 001 0 | 10 110 1 | 5 | 0 01 001 | 1 10 110 |
| 10 01 | 01 011 0 | 10 100 1 | 6 | 0 01 011 | 1 10 100 |
| 11 01 | 01 111 0 | 10 000 1 | 7 | 0 01 111 | 1 10 000 |
| 00 10 | 10 000 0 | 01 111 1 | 8 | 0 10 000 | 1 01 111 |
| 01 10 | 10 001 0 | 01 110 1 | 9 | 0 10 001 | 1 01 110 |
| 10 10 | 10 011 0 | 01 100 1 | A | 0 10 011 | 1 01 100 |
| 11 10 | 10 111 0 | 01 000 1 | B | 0 10 111 | 1 01 000 |
| 00 11 | 11 000 0 | 00 111 1 | C | 0 11 000 | 1 00 111 |
| 01 11 | 11 001 0 | 00 110 1 | D | 0 11 001 | 1 00 110 |
| 10 11 | 11 011 0 | 00 100 1 | E | 0 11 011 | 1 00 100 |
| 11 11 | 11 111 0 | 11 000 1 | F | 0 11 111 | 1 00 000 |

direction of transmission

Rule 9c: (without exchange of the sequence of the uncoded data
bits and coding according to rule 1b)

| LSB first | | | MSB first | | |
|---|---|---|---|---|---|
| Piece of | Code | Code | Value | Code | Code |
| Data | Word 1 | Word 2 | (hexadecimal) | Word 1 | Word 2 |
| 00 00 | 000 000 | 111 111 | 0 | 0 000 00 | 1 111 11 |
| 00 01 | 000 010 | 111 101 | 1 | 0 000 01 | 1 111 10 |
| 00 10 | 000 100 | 111 011 | 2 | 0 000 10 | 1 111 01 |
| 00 11 | 000 110 | 111 001 | 3 | 0 000 11 | 1 111 00 |
| 01 00 | 001 000 | 110 111 | 4 | 0 001 00 | 1 110 11 |
| 01 01 | 001 010 | 110 101 | 5 | 0 001 01 | 1 110 10 |
| 01 10 | 001 100 | 110 011 | 6 | 0 001 10 | 1 110 01 |
| 01 11 | 001 110 | 110 001 | 7 | 0 001 11 | 1 110 00 |
| 10 00 | 011 000 | 100 111 | 8 | 0 011 00 | 1 100 11 |
| 10 01 | 011 010 | 100 101 | 9 | 0 011 01 | 1 100 10 |
| 10 10 | 011 100 | 100 011 | A | 0 011 10 | 1 100 01 |
| 10 11 | 011 110 | 100 011 | B | 0 011 11 | 1 100 00 |
| 11 00 | 111 000 | 000 111 | C | 0 111 00 | 1 000 11 |
| 11 01 | 111 010 | 000 101 | D | 0 111 01 | 1 000 10 |
| 11 10 | 111 100 | 000 011 | E | 0 111 10 | 1 000 01 |
| 11 11 | 111 110 | 000 001 | F | 0 111 11 | 1 000 00 |

direction of transmission

Rule 9b is more favorable for simple decrementing during transmission with LSB first, because in this case, in order to avoid the non-data code word 010101 or 101010, after a “6” a level change always has to be avoided.

Now, the following general rules apply for the selection of the code:
1. if incrementing or decrementing is to take place, transmission is to be performed with LSB first
2. incrementing is more favorable according to rule 9 or 9.a
3. decrementing is more favorable according to rule 9.b or 9.c
4. if arbitrating is to take place, transmission is to be performed with MSB first
5. arbitrating is more favorable according to rule 9 or 9.a
6. the type of coding may be changed at will if it is known at which position using which code the work is to proceed.

In order to avoid code word 010101 or 101010, the rules in the following table are to be kept:

| | | | rule: no | follow-up rule: level |
|---|---|---|---|---|
| | | coding | level | change for balanced code |
| function | direction | rule | change | words |
| increment | LSB first | 9 | before “D” | necessary after D |
| increment | LSB first | 9.a | after “9” | — |
| decrement | LSB first | 9.b | after “6” | — |
| decrement | LSB first | 9.c | before “D” | necessary after D |
| arbitration | MSB first | 9 | after “A” | — |

Now, according to the present invention, for error detection and error correction, the decision for the current code data word is made a function of the current running digital sum RDS, that is, of the current digital sum in connection with the code generating rules. If this value were known to the receiver, especially to the second subscriber, then as was mentioned before, the selection of possible code data words could be limited to about half. Therefore it is provided, according to the present invention, to transmit the RDS periodically, in particular, and to process it further on this basis in the receiver until the next updating. Then it would also be possible to confirm the correctness of the data and/or data corrections up to now, using the newly received RDS value, or, if necessary, to generate an error signal that would put the previous data in question. These data, which are then detected as being erroneous, can then be checked again or even be discarded, along with a request for a repeated transmission of the data by the sender, that is, the first subscriber, in particular. If, for example, the EMC-reduced electrical transmission is based on a code as described in rule 9 that has already been mentioned, this raises the possibilities for information bits code word 1, code word 2 and value assignment (hexadecimal), as was described in connection with rule 9. This code of rule 9 has a code redundancy of 50%, and, without additional information about the RDS, it is not in a position to correct errors. On the contrary, single bit errors may here alreadey lead to another code word. If, for example, one takes code word 1 of hexadecimal value C as 111000 and corrupts only the last bit, one would obtain code word 2 of hexadecimal value 3 as 111001. Correspondingly, this yields the following adjacent traffic relationships between code data words:

| | | | |
|---|---|---|---|
| 111 000 | / | 111 001 | C/3 |
| 111 010 | / | 111 011 | D/2 |
| 111 100 | / | 111 101 | E/1 |
| 111 110 | / | 111 111 | F/0 |

This would have the result, if particularly the last code bit were corrupted, that one would have to count on a massive change in the value without an error detection possibility, provided that the transmission of the additional information, according to the present invention, is not ensured.

FIG. 9a shows once more symbolically, in a block 900, a code generator having alternative code words and low code redundancy, but different non-code data words. A transmission route is shown by 901 not having additional resources (lines/data). The information is transmitted by the selection of the alternative control words. Block 902 finally shows the receiver with the decoder, which recovers the information, that is, the RDS via the code generator decision criteria, especially from non-code data words or the control words, whereby the code data word selection becomes possible from the subset of all code data words, in order to perform an error detection and an error correction.

In FIG. 9b this is once more shown in greater detail. In 9b, the code generator is shown again by 900, the receiver having a decoder by 902 and the transmission route by 901, in addition, in code generator 900 various alternative code word data sets 903 to 905 being shown, which represent code data word sets 1, 2 to n. The actual coder is shown by 906 and the evaluating unit or rather the generating unit by block 907 for the additional information, precisely the RDS value by which then a certain code data word set, and from it a certain code data word, can be selected via a selection module 908.

Now, receiver 902 having the decoder is constructed analogously, in which also alternative code data word sets 1, 2 to n are shown by 909, 910 and 911, and via the evaluating or recovery module 912 additional information is ascertained from the RDS value, especially from the non-code data word, and consequently, a correct code data word is selected from the corresponding code data word sets, especially for the correction of the error, via selection module 913. The actual decoder is shown by 914.

Now, if the data are transmitted via the transmission route within the scope corresponding to FIGS. 10 and 10a, that is, frames each having i bytes, where i is, for example, 1, 2, 4, 8, 16, 32 and preferably 64, 128, 256, etc., and each frame begins with a preamble FP, which especially represents a non-code data word, the following possibilities come about: A particularly significant preamble, especially block preamble BP which, for instance is emitted after a fixed number j of frames instead of the frame preamble, if it is assumed that always j frames form a block of data, has the task of the first synchronization with the frame system, and must therefore not be created by the side-by-side arrangement of data words as partial bit patterns of this combination or be achieved in a different way using a combination of data. This reserved preamble has, for example, code 101010 or 010101. Since this preamble, with its continuous changes in bit values, causes a high EMV activity in the electrical transmission, it may also advantageously be used especially not for each frame, but, for example, only after a fixed number of frames, e.g. at the beginning of a block of j frames F1, F2, Fj (with j being, for example, 1, 2, 4, 8, preferably 16, 32, 64, etc.). Only when this preamble has been recognized are internal counters in the receiver set in such a way that it is known exactly when a frame begins and also when a block begins. At the beginning of block preamble BP a bit change should be avoided, in order to assure an exact synchronization. Since it is known after the first synchronization when a new frame is beginning, the frame preamble FP of the next frame and all subsequent frames is already expected and may be appropriately decoded, without being mistaken for a data word or for a combination of parts of two data words transmitted one after the other. Therefore, the frame preamble does not have to be sufficient for the requirement not to appear in the data pattern. For this reason, first of all the following code is proposed: 101110 and/or 010001. This value should be transmitted as preamble just when RDS is equal to zero or was zero before the emission of the preamble code. In the case of an DRS value of 0, since, according to a coding rule that is explained below, one always strives for a positive RDS value, one should sooner use the bit sequence 101110; the bit sequence 010001 may be used instead for transmitting additional information if this has been agreed upon in the coding rule. Since the above data code words have an even bit number (particularly 6, in this case), with each transmission of a data word either 0, 2, 4 or 6 is added to the RDS value, or the RDS value is decreased by this value. In normal, error-free operation, it is to be expected that, maximally, the absolute value 8 (+/−8) may occur, and the RDS value cannot become uneven in response to an even-numbererd number of code bits per word. These criteria may also be used for testing the plausibility of the received data. Additional frame preambles indicate what the RDS value of the transmitter was before the transmission of the preamble:

| | | |
|---|---|---|
| 101 110 | (010 001) | rds was 0(see above) (thereafter rds |
| | | becomes +2/(−2)) |
| 011 110 | 100 001 | rds was −2/+2 (thereafter rds becomes 0) |
| 011 000 | 100 111 | rds was +4/−4 (thereafter rds becomes +2/−2) |
| 101 000 | 010 111 | rds was +6/−6 (thereafter rds becomes +4/−4) |
| 010 010 | 101 101 | rds was +8/−8 (thereafter rds becomes +6/−6) |

All preambles having RDS information should have a Hamming distance of at least 2 from one another, in order for a single bit error in the preamble to be detectable. This is necessary because an error in the transmission of the RDS value may have. an effect on the following corrections. Furthermore, when RDS=0, for example, always a positive RDS or 0 should follow, in this case, this corresponding to an arbitrary coding rule as example for achieving unambiguity. Besides this, additional preambles may be used, such as:

| | | |
|---|---|---|
| 011 010 | 100 101 | frame preamble not having information |
| 001 100 | 110 011 | preamble for control purposes, not having |
| | | rds information |
| 010 100 | 101 011 | preamble for control purposes, not having |
| | | rds information |

Now, if, on account of the RDS information, an RDS counter is set, and a non-code data word is found in the following data words, it is easily determined, corresponding to the coding rule, whether it has to be a code word 1 or a code word 2, that is, according to rule 9, the least significant bit LSB is determined. Alternatively, this naturally works the same for rule 10, so that the most significant bit MSB is then determined. This means that the method produced with the aid of rule 9 naturally functions analogously for tule 10, and, to save ourselves the effort, it is not explicitly shown here once more.

In the case of an increase in the expenditure, according to the present invention, an additional improvement may now be achieved because, for instance, in the code of rule 9, not all single bit errors, for example, can now be taken into consideration, even if the named error correction information transmission is carried out, using RDS. There will always be error possibilities, beyond the case that was described. Thus, for instance, for some code words an error is not detectable if two data words differ in only one bit, that is, if a Hamming distance of 1 occurs. That is the case, for instance, for a change of bits 1 or 2. Thus, the data value 0 changes to data value 2 by an error in bit 2 of code word 1, according to rule 9.

In order to supply a complete correction possibility, the code redundancy would then have to be increased to the extent that all data words would have at least a Hamming distance of 3 with respect to one another. For this, more code bits at a correspondingly increased frequency would have to be transmitted, in order to assure the same information content per time unit. That is not to be recommended, if only because of the unfavorable EMV properties.

Thus, within the scope of a further development one should look for a possibility of undertaking a safe detection or even correction in the case of code redundancy that is not increased. Depending on the application, in this context, a correction may also be carried out that is not unequivocal. In the case of a plurality of possible correction words, one should decide on a specifiable strategy on which of the possible code words is to be selected, or whether perhaps a compromise is found which selects none of the possible code words, and instead, the arithmetic average of the value of all possible code words is used. A non-unique assignment during the correction has to be signaled, in this context, and it is also a component of the strategy that the correction is able to be prevented. This may take place by selecting an option, or even automatically, if too many corrections had already been undertaken.

With that, according to the present invention, the error detection is to be handled furthermore differentiated within the scope of further development, and, to be sure, in several steps:
(0) there is no error present, or at least no error is detectable.
(1) Error detection and correction to a unique value are possible (according to Hamming).
(2) Several code words are present which differ by exactly 1 bit from the received bit pattern and which at the same time satisfy the conditions with respect to the RDS and the level change mentioned. In this case (2) the correction takes place after a selectable strategy, such as, for instance,
   a minimum value of the possible code words
   a maximum value of the possible code words
   an arithmetic average of the possible code words (result does not necessarily correlate with the bit pattern received)
   interpolation of the data values (connection to velues received before)
   pulse suppression (fade out interference in the bit pattern, for instance, by a low-pass function)
   edge shift for bit pattern having in each case more than one constant bit value (adjustment of low-pass behavior or high-pass behavior of the transmission route)
   pulse generating as adjustment of the low-pass character of the transmission route
   no correction, but signaling of an error and transmitting a fixed specified data value, for instance, 0.
(3) error detection without correction possibility, for example, multiple bit errors (signaling of the error differentiated from point 2, if necessary) and transmitting a specified data value (e.g. 0) or a value that approximates the received value without taking into account the RDS value or the level change rule.

In point (0) there is no error present, or an error such as a single bit error or multiple bit error is not detectable because another data code word is created.

In point (1) an error is detected, and there is exactly one code word that is created by the change of a bit from the received word (only one code word within Hamming distance 1).

In point (2) there are several data code words that correspond to Hamming distance 1 to the received word. From this set of possible code words a value is selected according to a selectable strategy. The interpolation, for instance, is to be observed: It is meaningful, for example, if one knows the signal properties of a signal and, for instance, in the case of sensor signals or even audio signals, one knows that changes can come about only to a limited extent from sensor value to sensor value or from scanning value to scanning value according to the limiting frequency.

For this, in the error case, storing the current decoding conditions is meaningful, and an aftertreatment of the value, e.g. using interrupt to the controller is possible, according to FIG. 11. The number and type of corrections should also be stored, and, if necessary, in response to the exceeding of a specified number of such corrections, no further correction should be carried out according to point (2). This error memory may be completely or partially deleted as soon as new RDS information is transmitted, perhaps only if, upon comparing the internally calculated TDS information to the newly received value, no deviation or at least no great deviation is established. Thereby, the error correction is able to assume an adaptive character. However, the change in the strategy is also possible in a different way, in any desired manner, and may be influenced at any time by the user. Thus, for example, even in a learning phase, under realistic environmental conditions, the best correction possibility may be ascertained by oneself.

In the case of the signalization of an error, the strategy should particularly be changed if one or even more multiple bit errors have arisen. Then one may no longer rely on the RDS value calculated in the receiver. The error correction according to point (2) may be discontinued, just at least until a new current RDS value has been received again and no new multiple errors were detected.

Single bit errors that were not detected in the upper three bits have the effect of a value change of a maximum of 25% of the value range. Changes in the LSB may effect a total value change of 1 in F. That is excluded if the additional information, that is, RDS is available for decoding, and the corresponding coding conditions are present, that is, error correction information transfer by RDS transmission. In connection with the described RDS transfer, in many cases it may also be decided in which direction a correction has to take place. Thereby a uniquely valued correction may come about.

The following single bit errors according to rule 9 having the transmission direction LSB first are certainly determined in the case of non-code data words and are correctible:
errors in bit 5 (MSB), provided bit 4 is active.
errors in bit 4 (second highest bit), provided bit 5 is not active.
errors in bit 3 (third highest bit), provided bit 4 is not active.

In this instance, active means “1” in code word 1 and “0” in code word 2.

All other single bit changes cannot be detected or corrected if only one code word is observed. However, if the assumption is made that the code generating rule is known exactly, one may also undertake a correction from the information on the level change at the word limit in connection with the RDS information. In this context, according to the coding rule, a level change after a data word D must always take place if a balanced code word is transmitted. This applies also if several balanced data words after D succeed one another. Thereby a summing up of the RDS by several data words D (indirectly or directly) is prevented one after another. In the case of all other data words the level change is controlled by the RDS information.

At RDS=0, no negative value for RDS may be created by the code word, but rather a positive value that is as minimal as possible. In spite of the low code redundancy, additional corrections or suggestions for changes are thereby possible in response to single bit errors. In response to each correction of a valid code word into another one, an error information is additionally transmitted. Using an additional option, the corrections connected with this could be prevented. Then only the information on one error is output. All corrections have as a result at most 25% change in the value range of the data word.

In the case of a multiple error, for example, a fixed specified value is transmitted (and an interrupt). The strategy,decides if there is a possibility of deciding between several data words. A change in the strategy is possible by the error counter in FIG. 11. Then, if necessary, a correction is also prevented, that is, no correction is carried out, but a fixed value is taken. The counter in FIG. 11 is reset by updating the RDS value. For this, FIG. 11 shows once more receiver 902 having decoder 914 and transmitting route 901 in a symbolic representation with the sequence procedure.

First, the RDS information is particularly extracted from the non-code data word (or control word). RDS is compared via block 915 and block 916 (equivalent to block 912 in FIG. 9b) to the RDS information. In this context, increment/decrement is currently carried out. Subsequently, there takes place a periodic updating using a comparison (block 916). If the data word including RDS is error-free (block 917), the data word is output. Otherwise error correction 918 is reached, from which a corrected data word or a fixed data word comes about (Cf. also table 12). In case no correction is possible, an interruption (interrupt 919) takes place, especially using signaling, that no correction is possible, and giving an error indication. In response to an erroneous comparison of the RDS, an interrupt is also generated, especially having an error indication (920). Using error counter 921, said strategy specification may then take place in block 922 from the application having adjustment or adaptation possibility. Finally, at RDS updating, error counter 921 is reset, as was described above.

For this purpose, finally in Table 12 as variant 1a, a correction rule is described as an example for a partial correction at low code redundancy. In this context, a transmission using LSB first according to rule 9 is assumed. Furthermore, it is assumed for this example that in the case where no level change(/PV) is specified for a subsequent balanced code word (same number of zeros and ones), that then none shall take place either, provided this does not require another coding rule. This is the EMV-favorable variant, because, on the average, fewer level changes take place than in the case of other coding rules. This coding variant has a maximum run length (MRL) of 14.

The meanings in this context are:
MF: multiple bit error according to point (3) is present (error detected, but in general no correction possibility)
OK: no error detectable (point (0))
PV: level change provided for balanced code word (directly or indirectly after D)
/PV: no level change permitted for balanced code word
PE: level change is present: current LSB unequal to last bit value
/PE: no level change takes place (current LSB=last bit value of last code word)
X.1: code word 1 for data word X (e.g. D.1 for D, C.1 for C, 5.1 for 5, etc.)
X.2: code word 2 for data word X (e.g. F.2 for F, E.2 for E, 6.2 for 6, etc.)
n.d: no data code word, also non-code data word: In place of a preamble, special conditions apply

In the case of some bit values, an error in one of the values is possible (correction according to point (2) or point (1))

In the following, the columns in Table 12 are described:

1^{st} column: all code words

2nd column: meaning as data word (code data word) or non-data word (non-code data word)

3rd column: condition in this case was rds<=0, for balanced code word, level change is specified (PV), a level change is present(PE), correction possibility to stated code words (or OK, MF)

4^{th} column: condition in this case was rds<=0, for balanced code word, level change is specified (PV), no level change is present(/PE), correction possibility to stated code words (or OK, MF)

5^{th} column: Condition in this case was rds<=0, for balanced code word no level change is specified (/PV) and, in this case, according to the selected coding rule, no level change should take place for such a code word, a level change is present (PE), correction possibility to stated code words (or OK, MF)

6^{th} column: condition in this case was rds<=0, for balanced code word, no level change is specified (/PV), and should also not take place (s.o.), no level change is present (/PE), correction possibility to stated code words (or OK, MF)

7h column: condition in this case was rds<0, for balanced code word, level change is specified (PV), a level change is present(PE), correction possibility to stated code words (or OK, MF)

8^{th} column: condition in this case was rds>0, for balanced code word, level change is specified (PV), no level change is present(/PE), correction possibility to stated code words (or OK, MF)

9^{th} column: condition in this case was rds>0, for balanced code word, no level change is specified (/PV), and should also not take place (s.o.), a level change is present (PE), correction possibility to stated code words (or OK, MF)

10^{th} column: condition in this case was rds>0, for balanced code word, no level change is specified (/PV), and should also not take place (s.o.), no level change is present (/PE), correction possibility to stated code words (or OK, MF)

Using the Variant

Variant 1b LSB First

This coding variant is similar to the one described in variant 1a: coding according to rule 9 and transmission direction LSB first. The difference is only in the rule for a forced level change for balances code words, provided no other rule opposes it. Using this coding rule, a maximum run length (MRL) is attained by 13, which is more favorable for a PLL. For this, the EMV characteristics values are slightly worse. The following code correction table differs slightly from the one described in Table 12.

Legend:
MF: multiple bit error according to point 3 is present (error detected, but in general no correction possibility)
OK: no error detectable (point 0)
PV: level change provided for balanced code word (directly or indirectly after D),
/PV: no level change provided for balanced code word (directly or indirectly after D), but deviating here: otherwise level change specified for balanced code words
PE: level change is present: current LSB=last bit value;
/FE: no level change is present: current LSB=last bit value;
X.1: code word 1 for data word X
X.2: code word 2 for data word X
n.d. no data code word; instead of a preamble, special conditions apply

bit values in bold: error in one of the values is possible (correction according to point 2 or 1), if necessary, conditional

TABLE 1
Code correction rule as example for a partial
correction at low code redundancy
for variant b):

| code | data | | | | | | | | |
|---|---|---|---|---|---|---|---|---|---|
| word | word | | | | | | | | |
| PV under PE: | | | | | | | | | |
| conditions for | | | | | | | | | |
| level change | | rds <= 0 | | | | rds > 0 | | | |
| at beginning | | PV | PV | /PV | /PV | PV | PV | /PV | /PV |
| of word | | PE | /PE | PE | /PE | PE | /PE | PE | /PE |
| 000000 | 0.1 | MF | | | | OK | | | |
| 000001 | F.2 | | | | | | | | |
| 000010 | 1.1 | | | | | | | | |
| 000011 | E.2 | C.2, | MF | C.2, | MF | | | | |
| | | A.2 | | A.2 | | | | | |
| 000100 | 2.1 | MF | | | | | | | |
| 000101 | D.2 | C.2, | OK | C.2, | OK | 2.1, | OK | 2.1, | OK |
| | | 9.2 | | 9.2 | | 9.2, | | 9.2, | |
| | | | | | | C.2, | | C.2, | |
| | | | | | | F.2 | | F.2 | |
| 000110 | 3.1 | 7.1 | C.2 | 7.1 | C.2 | OK | | | |
| 000111 | C.2 | OK | 8.2 | OK | 8.2 | OK | D.2, | OK | D.2, |
| | | | | | | | 3.1, | | 3.1, |
| | | | | | | | E.2 | | E.2 |
| 001000 | n.d. | MF | | | | B.2, 0.1 | | | |
| 001001 | B.2 | 9.2, | MF | 9.2, | MF | OK | | | |
| | | A.2 | | A.2 | | | | | |
| 001010 | n.d. | MF | A.2 | MF | A.2 | 1.1 | A.2, | 1.1 | A.2, |
| | | | | | | | 1.1 | | 1.1 |
| 001011 | A.2 | OK | 6.2, | OK | 6.2, | OK | B.2, | OK | B.2, |
| | | | 8.2 | | 8.2 | | E.2 | | E.2 |
| 001100 | n.d. | MF | 9.2 | MF | 9.2 | 2.1 | 2.1, | 2.1 | 2.1, |
| | | | | | | | 9.2 | | 9.2 |
| 001101 | 9.2 | OK | 5.2, | OK | 5.2, | OK | B.2, | OK | B.2 |
| | | | 8.2, | | 8.2, | | D.2 | | D.2 |
| | | | D.2 | | D.2 | | | | |
| 001110 | n.d. | 8.2 | | | | 3.1 | | | |
| 001111 | 8.2 | OK | | | | 9.2, | MF | 9.2, | MF |
| | | | | | | A.2, | | A.2, | |
| | | | | | | C.2 | | C.2 | |
| 010000 | n.d. | MF | | | | 0.1, 8.1 | | | |
| 010001 | n.d. | 7.2 | MF | 7.2 | MF | 7.2, | F.2 | 7.2, | F.2 |
| | | | | | | F.2 | | F.2 | |
| 010010 | n.d. | 9.1 | MF | 9.1 | MF | 1.1, | 1.1 | 1.1, | 1.1 |
| | | | | | | 9.1 | | 9.1 | |
| 010011 | n.d | 6.2 | | | | E.2 | | | |
| 010100 | n.d. | A.1 | MF | A.1 | MF | 2.1, | 2.1 | 2.1, | 2.1 |
| | | | | | | A.1 | | A.1 | |
| 010101 | n.d. | 5.2 | D.2, | 5.2 | D.2, | MF | D.2 | MF | D.2 |
| | | | 5.2 | | 5.2 | | | | |
| 010110 | n.d. | B.1 | | | | 3.1 | | | |
| 010111 | n.d. | 4.2, | 4.2 | 4.2, | 4.2 | C.2 | MF | C.2 | MF |
| | | C.2 | | C.2 | | | | | |
| 011000 | n.d. | C.1 | 7.2 | C.1 | 7.2 | C.1 | 7.2 | C.1 | 7.2 |
| 011001 | 7.2 | OK | 5.2, | OK | 5.2, | OK | B.2 | OK | B.2 |
| | | | 6.2 | | 6.2 | | | | |
| 011010 | n.d. | 6.2 | D.1, | 6.2 | D.1, | MF | D.1 | MF | D.1 |
| | | | 6.2 | | 6.2 | | | | |
| 011011 | 6.2 | OK | | | | 7.2, | MF | 7.2, | MF |
| | | | | | | A.2 | | A.2 | |
| 011100 | n.d. | 5.2, E.1 | | | | MF | | | |
| 011101 | 5.2 | OK | | | | 7.2, | MF | 7.2, | MF |
| | | | | | | 9.2 | | 9.2 | |
| 011110 | n.d. | 4.2, F.1 | | | | MF | | | |
| 011111 | 4.2 | OK | | | | MF | | | |
| 100000 | 4.1 | MF | | | | OK | | | |
| 100001 | n.d. | MF | | | | 4.1, F.2 | | | |
| 100010 | 5.1 | 7.1, | MF | 7.1, | MF | OK | | | |
| | | 9.1 | | 9.1 | | | | | |
| 100011 | n.d. | MF | | | | 5.1, E.2 | | | |
| 100100 | 6.1 | 7.1, | MF | 7.1, | MF | OK | | | |
| | | A.1 | | A.1 | | | | | |
| 100101 | n.d. | MF | D.2 | MF | D.2 | 6.1 | 6.1, | 6.1 | 6.1, |
| | | | | | | | D.2 | | D.2 |
| 100110 | 7.1 | OK | B.1 | OK | B.1 | OK | 5.1, | OK | 5.1, |
| | | | | | | | 6.1 | | 6.1 |
| 100111 | n.d. | C.2 | 7.1 | C.2 | 7.1 | C.2 | 7.1 | C.2 | 7.1 |
| 101000 | n.d. | C.1 | MF | C.1 | MF | 4.1, | 4.1 | 4.1, | 4.1 |
| | | | | | | C.1 | | C.1 | |
| 101001 | n.d. | 3.2 | | | | B.2 | | | |
| 101010 | n.d. | MF | D.1 | MF | D.1 | 5.1 | D.1, | 5.1 | D.1, |
| | | | | | | | 5.1 | | 5.1 |
| 101011 | n.d. | 2.2, | 2.2 | 2.2, | 2.2 | A.2 | MF | A.2 | MF |
| | | A.2 | | A.2 | | | | | |
| 101100 | n.d. | E.1 | | | | 6.1 | | | |
| 101101 | n.d. | 1.2, | 1.2 | 1.2, | 1.2 | 9.2 | MF | 9.2 | MF |
| | | 9.2 | | 9.2 | | | | | |
| 101110 | n.d. | 7.1, | F.1 | 7.1, | F.1 | 7.1 | MF | 7.1 | MF |
| | | F.1 | | F.1 | | | | | |
| 101111 | n.d. | 0.2, 8.2 | | | | MF | | | |
| 110000 | 8.1 | 9.1, | MF | 9.1, | MF | OK | | | |
| | | A.1, | | A.1, | | | | | |
| | | C.1 | | C.1 | | | | | |
| 110001 | n.d. | 3.2 | | | | | | | |
| 110010 | 9.1 | OK | B.1, | OK | B.1, | OK | 5.1, | OK | 5.1 |
| | | | D.1 | | D.1 | | 8.1, | | 8.1, |
| | | | | | | | D.1 | | D.1 |
| 110011 | n.d. | 2.2 | 2.2, | 2.2 | 2.2, | MF | 9.1 | MF | 9.1 |
| | | | 9.1 | | 9.1 | | | | |
| 110100 | A.1 | OK | B.1, | OK | B.1, | OK | 6.1, | OK | 6.1, |
| | | | E.1 | | E.1 | | 8.1 | | 8.1 |
| 110101 | n.d. | 1.2 | A.1, | 1.2 | A.1, | MF | A.1 | MF | A.1 |
| | | | 1.2 | | 1.2 | | | | |
| 110110 | B.1 | OK | | | | 9.1, | MF | 9.1, | MF |
| | | | | | | A.1 | | A.1 | |
| 110111 | n.d. | 0.2, B.1 | | | | MF | | | |
| 111000 | C.1 | OK | 3.2, | OK | 3.2, | OK | 8.1 | OK | 8.1 |
| | | | D.1, | | D.1, | | | | |
| | | | E.1 | | E.1 | | | | |
| 111001 | 3.2 | OK | | | | 7.2 | C.1 | 7.2 | C.1 |
| 111010 | D.1 | F.1, | OK | F.1, | OK | C.1, | OK | C.1, | OK |
| | | 2.2, | | 2.2, | | 9.1 | | 9.1 | |
| | | C.1, | | C.1, | | | | | |
| | | 9.1 | | 9.1 | | | | | |

| | | | |
|---|---|---|---|
| 111011 | 2.2 | OK | MF |

| | | | | | |
|---|---|---|---|---|---|
| 111100 | E.1 | C.1, | MF | C.1, | MF |
| | | | A.1 | | A.1 |

| | | |
|---|---|---|
| 111101 | 1.2 | MF |
| 111110 | F.1 | |
| 111111 | 0.2 | |

Explanation of the table:
column 1: all 2⁶ code words
column 2: meaning as data word or non-data word
column 3: condition in this case was rds<=0, for balanced code word, level change is specified (PV), a level change is present(PE), correction possibility to stated code words (or OK, MF)
column 4: condition in this case was rds<=0, for balanced code word, level change is specified (PV), no level change is present(/PE), correction possibility to stated code words (or OK, MF)
column 5: condition in this case was rds<=0, for balanced code word, no level change is specified (/PV), however, corresponding to PLL condition, no level change should take place, a level change is present (PE), correction possibility to stated code words (or OK, MF)
column 6: condition in this case was rds<=0, for balanced code word, no level change is specified (/PV), however, corresponding to PLL condition, a level change should take place, no level change is present (/PE), correction possibility to stated code words (or OK, MF)
column 7: condition in this case was rds>0, for balanced code word, level change is specified (PV), a level change is present(PE), correction possibility to stated code words (or OK, MF)

Variant 2

As was described in the preceding remarks, the code for the transmission using MSB first according to rule 10 applies, with the following deviations:

It is to be noted that the inverting bit is always sent first (independently of whether one begins with the LSB or the MSB). The rules for avoiding the bit sequence 101010 by the composition of coded data words according to the exemplary embodiment of rule 9 LSB are to be adjusted correspondingly:
1. If a change is made from LSB first to MSB first, there exists no rule with regard to inverting besides reducing the RDS value.
2. Between two MSB first values, a level change (instead of before “d”) after hexadecimal value “a” MSB first (0110101 or 100101) has to be avoided.
3. For all balanced code words after an “a” there is no rule in this case, since “a” itself is balanced (no RDS value change with a, whereby no rule for indirectly successive “a”'s is required).
4. For a transfer from MSB first to LSB first, a level change should generally be prevented if the last 3 bits were alternating (after to 2, 6, a, d).
5. For a following “d” in LSB first, the same conditions apply as otherwise, (that is, no level change).

The coding according to rule 10 has a maximum run length (MRL) of 12 for MSB first, independently of whether coding is suitable for EMV or PLL.

In an exemplary fashion, in this case both variants are recorded in the table. A more exact coding rule leads to more clear-cut corrections in the case that no level equality is required (/GV, see below).

Legend:
MF: multiple bit error according to 3 is present (error detected, but in general no correction possibility)
OK: no error detectable (point 0)
GV: equal level provided for balanced code word (after A): no level change permitted!
/GV: no level equality required in the case of balanced code word; either
a) the level should remain the same (EMV reduction, uniqueness)
b) or the level should change (PLL activity, uniqueness)
G: same signal level is present: current MSB=last bit value (no level change)
/G: level change is present: current MSB=last bit value;
X.1: code word 1 for data word X
X.2: code word 2 for data word X
n.d. no data code word; instead of a preamble, special conditions apply

bit values in bold: error in one of the values is possible (correction according to point 2 or 1), if necessary, conditional

TABLE 2
Code correction rule as example for a partial
correction at low code redundancy
without taking into consideration the precedence at
balanced code word with /GV.
For variant a), as a rule, the value is to be replaced
correspondingly as follows:
column /GV and G: as column GV and /G:
column /GV and /G: as column GV and G:
For variant a), as a rule, at /GV the value is to be
replaced correspondingly as follows:
column /GV and G: as column GV and G:
column /GV and /G: as column GV and G:
the substitutions apply in each case for rds <= 0 and
rds >0 correspondingly.

| | |
|---|---|
| code | data |
| word | word |

| GV and PE | | | | | | | | |
|---|---|---|---|---|---|---|---|---|
| (conditions for | | | | | | | | |
| level change | rds <= 0 | | | | rds > 0 | | | |
| at beginning | GV | GV | /GV | /GV | GV | GV | /GV | /GV |
| of word) | G | /G | G | /G | G | /G | G | /G |

| 000000 | 0.1 | MF | | | OK | | |
|---|---|---|---|---|---|---|---|
| 000001 | 1.1 | | | | | | |
| 000010 | 2.1 | | | | | | |
| 000011 | 3.1 | 7.1 | C.2 | 7.1, C.2 | | | |
| 000100 | n.d. | MF | | | 0.1, B.2 | | |
| 000101 | n.d. | MF | A.2 | | 1.1, A.2 | | |
| 000110 | n.d. | MF | 9.2 | | 2.1, 9.2 | | |
| 000111 | n.d. | 8.2 | | | 3.1 | | |
| 001000 | n.d. | | MF | | 0.1 | | |
| 001001 | n.d. | | | | 1.1 | | |
| 001010 | n.d. | | | | 3.1 | | |
| 001011 | n.d. | | | | 3.1 | | |
| 001100 | n.d. | C.1 | 7.2 | 7.2, C.1 | C.1 | 7.2 | 7.2, C.1 |
| 001101 | n.d. | 6.2, D.1 | | | MF | | |
| 001110 | n.d. | 5.2, E.1 | | | | | |
| 001111 | n.d. | 4.2, F.1 | | | | | |
| 010000 | 4.1 | MF | | | OK | | |
| 010001 | 5.1 | 7.1, | MF | 7.1, 9.1 | | | |
| | | 9.1 | | | | | |
| 010010 | 6.1 | 7.1, | | | | | |
| | | A.1 | | | | | |
| 010010 | 7.1 | B.1 | | | 3.1, 5.1, 6.1 | | |
| 010100 | n.d. | C.1 | MF | C.1 | 4.1 | 4.1 | 4.1, C.1 |
| | | | | | C.1 | | |

| 010101 | n.d. | D.1 | 5.1 | | |
|---|---|---|---|---|---|
| 010110 | n.d. | E.1 | 6.1 | | |
| 010111 | n.d. | F.1 | 7.1 | MF | 7.1 |

| | | | | | | |
|---|---|---|---|---|---|---|
| 011000 | 8.1 | 9.1, | MF | 9.1, | A.1, | OK |
| | | A.1 | | C.1 | | |
| | | C.1 | | | | |

| 011001 | 9.1 | OK | MF | OK | OK | MF | OK |
|---|---|---|---|---|---|---|---|
| 011010 | A.1 | OK | MF | OK | OK | MF | OK |
| 011011 | B.1 | OK | | | 7.1, | MF | 7.1, 9.1, A.1 |
| | | | | | 9.1 | | |
| | | | | | A.1 | | |
| 011100 | C.1 | OK | 3.2, | OK | OK | 3.2, | |
| | | | D.1, | | | D.1 | |
| | | | E.1 | | | E.1 | |
| 011101 | D.1 | OK | | | 9.1, | MF | 9.1, C.1 |
| | | | | | C.1 | | |
| 011110 | E.1 | | | | A.1, | MF | A.1, C.1 |
| | | | | | C.1 | | |
| 011111 | F.1 | | | | MF | | |
| 100000 | F.2 | MF | | | OK | | |
| 100001 | E.2 | A.2, | MF | 1.2, C.2 | | | |
| | | C.2 | | | | | |
| 100010 | D.2 | 9.2, | | 9.2, C.1 | | | |
| | | C.2 | | | | | |
| 100011 | C.2 | OK | MF | OK | OK | MF | OK |
| 100100 | B.2 | 7.1, | MF | 7.1, 9.1, A.1 | OK | | |
| | | 9.1, | | | | | |
| | | A.1 | | | | | |
| 100101 | A.2 | OK | MF | OK | OK | MF | OK |
| 100110 | 9.2 | OK | MF | OK | OK | MF | OK |

| | | | | | | |
|---|---|---|---|---|---|---|
| 100111 | 8.2 | OK | 9.2, | MF | 9.2, | A.2, |
| | | | A.2, | | C.2 | |
| | | | C.2 | | | |

| | | | | | | | | |
|---|---|---|---|---|---|---|---|---|
| 101000 | n.d. | 7.2 | MF | 7.2 | 7.2 | 7.2 | F.2 | 7.2, F.2 |
| | | | | | | F.2 | | |

| 101001 | n.d. | 6.2 | | | E.2 | | |
|---|---|---|---|---|---|---|---|
| 101010 | n.d. | 5.2 | | | D.2 | | |
| 101011 | n.d. | 4.2 | | | C.2 | MF | C.2 |
| 101100 | 7.2 | OK | 3.2 | OK | OK | B.2 | |
| 101101 | 6.2 | OK | | | A.2, | MF | A.2, 7.2 |
| | | | | | 7.2 | | |
| 101110 | 5.2 | OK | | | 9.2 | MF | 9.2, 7.2 |
| | | | | | 7.2 | | |
| 101111 | 4.2 | OK | | | MF | | |
| 110000 | n.d. | MF | | | 4.1, F.2 | | |
| 110001 | n.d. | MF | | | 5.1, E.2 | | |
| 110010 | n.d. | MF | | | 6.1, D.2 | | |
| 110011 | n.d. | C.2 | 7.1 | 7.1, C.2 | C.2 | 7.1 | 7.1, C.2 |
| 110100 | n.d. | 3.2 | | | B.2 | | |
| 110101 | n.d. | 2.2 | 2.2 | 2.2, A.2 | A.2 | MF | A.2 |
| | | A.2 | | | | | |
| 110110 | n.d. | 1.2, | 1.2 | 1.2, 9.2 | 9.2 | MF | 9.2 |
| | | 9.2 | | | | | |

| 110111 | n.d. | 0.2, 8.2 | MF | | |
|---|---|---|---|---|---|
| 111000 | n.d. | 3.2 | 8.1 | | |
| 111001 | n.d. | 2.2 | 9.1 | MF | 9.1 |
| 111010 | n.d. | 1.2 | A.1 | MF | |
| 111011 | n.d. | 0.2, B.1 | MF | | |
| 111100 | 3.2 | OK | 7.2 | C.1 | 7.2, C.1 |

| | | |
|---|---|---|
| 111101 | 2.2 | MF |
| 111110 | 1.2 | |
| 111111 | 0.2 | |

Explanation of the table:
column 1: all 2⁶ code words
column 2: meaning as data word or non-data word
column 3: condition in this case was rds<=0, for balanced code word, level change is specified (PV), a level change is present(PE), correction possibility to stated code words (or OK, MF)
column 4: condition in this case was rds<=0, for balanced code word, level change is specified (PV), no level change is present(/PE), correction possibility to stated code words (or OK, MF)
column 5: condition in this case was rds<=0, for balanced code word, no level change is specified (/PV), a level change is present(PE), depending on coding rule (suitable for EMV according to variant a) or suitable for PLL according to variant b) a level change should take place in the case of balanced code words; correction possibility to stated code words (or OK, MF),if condition is not specified, otherwise to corresponding code according to column 4 in variant a) or column 3 in variant b)
column 6: condition in this case was rds<=0, for balanced code word, no level change is specified (/PV), no level change is present(/PE), depending on coding rule (suitable for EMV according to variant a) or suitable for PLL according to variant b) a level change should take place in the case of balanced code words; correction possibility to stated code words (or OK, MF),if condition is not specified, otherwise to corresponding code according to column 3 in variant a) or column 4 in variant b)
column 7: condition in this case was rds>0, for balanced code word, level change is specified (PV), a level change is present(PE), correction possibility to stated code words (or OK, MF)

Additional exemplary embodiments:

The method according to the present invention is not limited to systematic codes. In particular, any coding rules of a block code (as, for instance, in the one of the article mentioned) is treatable in the same way if a code word is always selected while taking into consideration the RDS from a set of alternative equal-valued code words. In the general case, one may take any clear-cut coding rule, supplement all the binary code words with a zero, and assign the same data value to the resulting code word when inverting all bits of these code words including the supplemented bit value 0. Then I select either the first or the modified code word, with the aid of an RDS value.

1-15. (canceled)

16. A method for error handling in the transmission of coded data in the form of at least one data word via a communications system, comprising: selecting a code data word for the at least one data word according to a specifiable coding rule, and representing the data as bits which are able to assume two different values, ones and zeros, forming at least one running digital sum in such a way that a summed difference of the total number of the ones and the total number of the zeros being formed at least through the code data word and this running digital sum is transmitted, said running digital sum having influence on the coding rule for the data word, the running digital sum being determined in consideration of all following code data words, and checking therewith the coding rule for each individual code data word, and in the case of deviation, detecting errors.

17. The method according to claim 16, wherein besides the coded data, also at least one non-code data word is transmitted between a first subscriber and at least a second subscriber, which is not coded according to the specifiable coding rule, and the running digital sum is transmitted at least as a part of the non-code data word.

18. The method according to claim 16, wherein the code word selected according to the specifiable coding rule corresponds in each case to a first or a second code word which represent code words inverted with respect to each other.

19. The method according to claim 16, wherein the code word selected according to the specifiable coding rule is able to be selected from at least two different code word sets corresponding to the coding rule.

20. The method according to claim 16, wherein the running digital sum is formed over several code data words, and it is checked whether it exceeds a specifiable maximum amount, an error then being detected.

21. The method according to claim 16, wherein when an error is detected, an error signal of the first subscriber that has detected the error is generated and the error signal is transmitted at least to the second subscriber.

22. The method according to claim 16, wherein in response to the detection of an error, the erroneous data are discarded and the subscriber transmitting these data receives a request signal to transmit these data again.

23. The method according to claim 16, wherein besides the coded data, also at least one non-code data word is transmitted between the first subscriber and the at least second subscriber, which is not coded according to the specifiable coding rule, and the running digital sum is also formed through the non-code data word.

24. The method according to claim 16, wherein a correction of the error is undertaken in that, depending on the running digital sum, the following running digital sum is ascertained anew, and depending on this, the erroneous data are replaced.

25. The method according to claim 16, wherein a strategy specification for error handling takes place as a function of the number of errors.

26. The method according to claim 16, wherein the strategy provides not to undertake any error correction under specifiable assumptions.

27. The method according to claim 16, wherein a correction of the error is undertaken in that the erroneous data word is replaced by a certain stipulated data word.

28. A device for error handling in the transmission of coded data in the form of at least one data word via a communications system, a code data word being selected for the at least one data word according to a specifiable coding rule, the data being represented as bits which are able to assume two different values, ones and zeros,
wherein at least one running digital sum is formed in such a way that a summed difference of the total number of the ones and the total of the zeros is at least formed through the code data word and this running digital sum is transmitted, the running digital sum being determined to the following code data word and being compared to the one that is then transmitted, and in the case of deviation, an error being detected.

29. A subscriber having a device for error handling in the transmission of coded data in the form of at least one data word via a communications system, a code data word being selected for the at least one data word according to a specifiable coding rule, the data being represented as bits which are able to assume two different values, ones and zeros,
wherein at least one running digital sum is formed in such a way that a summed difference of the total number of the ones and the total number of the zeros is at least formed through the code data word and this running digital sum is transmitted, the running digital sum being determined to the following code data word and being compared to the one that is then transmitted, and in the case of deviation, an error being detected.

30. A computer program product having program code that is stored on a data carrier, for carrying out the method according to claim 1, if the program is run in a computer-assisted communications system.

31. A computer program having program code for carrying out the method according to claim 1, if the program is executed in a computer-assisted communications system.
